(19) United States
(12) Patent Application Publication
(10) Pub. No.: US 2023/0230900 A1
(43) Pub. Date: Jul. 20, 2023

(54) SEMICONDUCTOR DEVICE

(71) Applicant: FUJI ELECTRIC CO., LTD., Kawasaki-shi (JP)

(72) Inventor: Reika UCHIMI, Matsumoto-city (JP)

(73) Assignee: FUJI ELECTRIC CO., LTD., Kawasaki-shi (JP)

(21) Appl. No.: 18/071,181

(22) Filed: Nov. 29, 2022

(30) Foreign Application Priority Data
Jan. 14, 2022 (JP) 2022-004508

(51) Int. Cl. H01L 23/473; H01L 23/10

(52) U.S. Cl. CPC H01L 23/473; H01L 23/10

(57) ABSTRACT

An outer frame (outer wall) of a housing of a semiconductor device has a spacer portion that protrudes beyond a bottom surface of a cooling bottom plate in an opposite direction to a semiconductor chip. When the semiconductor device is placed on an arbitrary placement surface for example, the spacer portion produces a gap between a rear surface of a cooling device (that is, a bottom surface of the cooling bottom plate) and the placement surface. This means that the bottom surface of the cooling bottom plate does not directly touch the placement surface and is less likely to be damaged. Favorable sealing is maintained between pipes, which are attached to the cooling device of the semiconductor device, and an inlet and an outlet on the cooling bottom plate.

### CROSS-REFERENCE TO RELATED APPLICATION

This application is based upon and claims the benefit of priority of the prior Japanese Patent Application No. 2022-004508, filed on Jan. 14, 2022, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device includes a semiconductor module and a cooling device. The semiconductor module includes a power semiconductor element and is mounted on the cooling device. Coolant passes through the cooling device. By doing so, the cooling device cools the semiconductor module that heats up during use, which ensures the semiconductor module operates reliably.

The cooling device has openings formed on a rear surface as an inlet and outlet for the coolant. Coolant pipes are aligned with these openings and then installed with sealing members (as examples, O-rings or rubber seals) interposed between the coolant pipes and regions (or “sealing regions”) that surround the openings (see, for example, Japanese Laid-open Patent Publication No. 2020-092250).

In this way, coolant pipes are attached to the openings on the rear surface of a bottom plate of the cooling device. To do so, the sealing regions around the openings need to be free of damage. When a coolant pipe is attached via a sealing member to a sealing region that has been damaged, there may be deterioration in the seal achieved by the sealing member, resulting in the risk of the coolant leaking. When the coolant leaks, there would be a drop in the cooling achieved by the cooling device, which prevents the semiconductor module from being sufficiently cooled. This may lead to a drop in reliability for the semiconductor device.

### SUMMARY OF THE INVENTION

According to one aspect of the present embodiments, there is provided a semiconductor device, including: a semiconductor chip; and a housing including an outer frame and a cooling device, wherein the cooling device includes: a top plate that has the semiconductor chip mounted on a front surface thereof; a bottom plate that faces the top plate and has openings through each of which coolant flows in or out of the cooling device; and a side wall that forms a continuous ring in a plan view of the semiconductor device, is interposed between the top plate and the bottom plate, and defines a flow path region within the ring, through which the coolant flows, and the housing further includes a spacer portion that protrudes from a bottom surface of the bottom plate in a direction away from the semiconductor chip.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a side view of the semiconductor device according to the first embodiment;

FIG. 3 is a cross-sectional view of the semiconductor device according to the first embodiment;

FIG. 4 is a rear view of the semiconductor device according to the first embodiment;

FIG. 5 is a plan view of a semiconductor unit included in the semiconductor device according to the first embodiment;

FIG. 6 is a cross-sectional view of the semiconductor unit included in the semiconductor device according to the first embodiment;

FIG. 7 is a first perspective view of a cooling device included in the semiconductor device according to the first embodiment;

FIG. 8 is a second perspective view of the cooling device included in the semiconductor device according to the first embodiment;

FIG. 9 is a rear view of the cooling device included in the semiconductor device according to the first embodiment;

FIG. 10 depicts a flow of coolant in the cooling device included in the semiconductor device according to the first embodiment;

FIG. 11 is a cross-sectional view of a semiconductor device according to a modification 1-1 of the first embodiment;

FIG. 12 is a cross-sectional view of a semiconductor device according to a modification 1-2 of the first embodiment;

FIG. 13 is a rear view of a semiconductor device according to a modification 1-3 of the first embodiment;

FIG. 14 is a side view of a semiconductor device of a modification 1-4 of the first embodiment;

FIG. 15 is a rear view of the modification 1-4 of the semiconductor device of the first embodiment;

FIG. 16 is a first rear view of a semiconductor device according to a modification 1-5 of the first embodiment;

FIG. 17 is a second rear view of the semiconductor device according to the modification 1-5 of the first embodiment;

FIG. 18 is a cross-sectional view of a semiconductor device according to a second embodiment;

FIG. 19 is a rear view of the semiconductor device according to the second embodiment;

FIG. 20 is a cross-sectional view of a semiconductor device according to a modification 2-1 of the second embodiment;

FIG. 21 is a rear view of a semiconductor device according to a modification 2-1 of the second embodiment;

FIG. 22 is a cross-sectional view of a semiconductor device according to a modification 2-2 of the second embodiment; and

FIG. 23 is a rear view of the semiconductor device according to the modification 2-2 of the second embodiment.

### DETAILED DESCRIPTION OF THE INVENTION

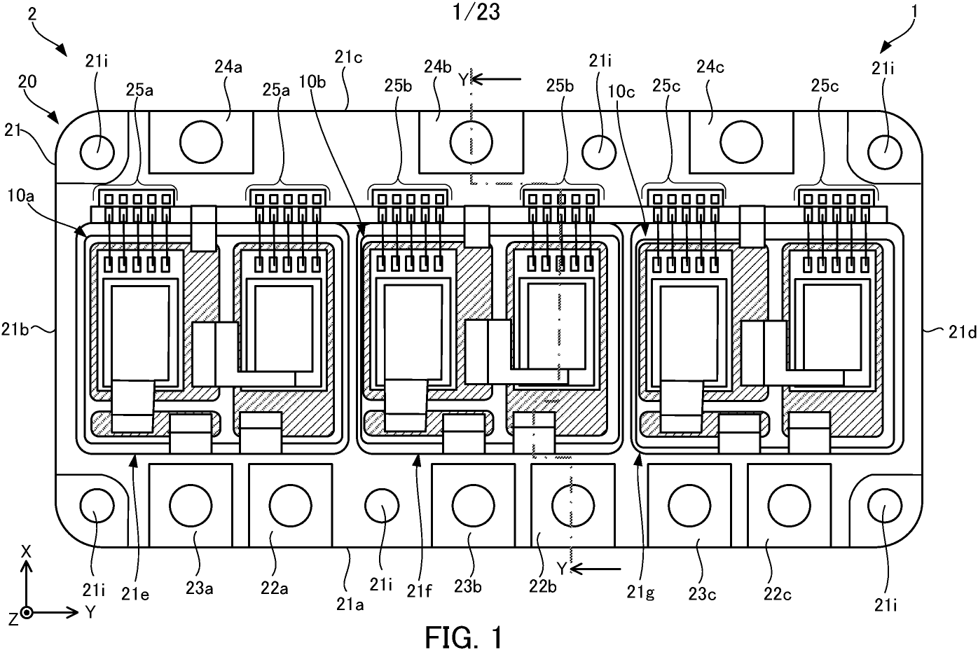

Several embodiments will be described below with reference to the accompanying drawings. Note that in the following description, the expressions “front surface” and “upper surface” refer to an X-Y plane that faces upward (in the “+Z direction”) for a semiconductor device 1 depicted in FIG. 1. In the same way, the expression “up” refers to the upward direction (or “+Z direction”) for the semiconductor device 1 depicted in FIG. 1. The expressions “rear surface” and “lower surface” refer to an X-Y plane that faces downward (that is, in the “-Z direction”) for the semiconductor device 1 depicted in FIG. 1. In the same way, the expression “down” refers to the downward direction (or “-Z direction”) for the semiconductor device 1 depicted in FIG. 1. These expressions are used as needed to refer to the same directions in the other drawings. The expressions “front surface”, “upper surface”, “up”, “rear surface”, “lower surface”, “down”, and “side surface” are merely convenient expressions used to specify relative positional relationships, and are not intended to limit the technical scope of the present embodiments. As one example, “up” and “down” do not necessarily mean directions that are perpendicular to the ground. That is, the “up” and “down” directions are not limited to the direction of gravity. Additionally, in the following description, the expression “main component” refers to a component that composes 80% or higher by volume out of all the components.

### First Embodiment

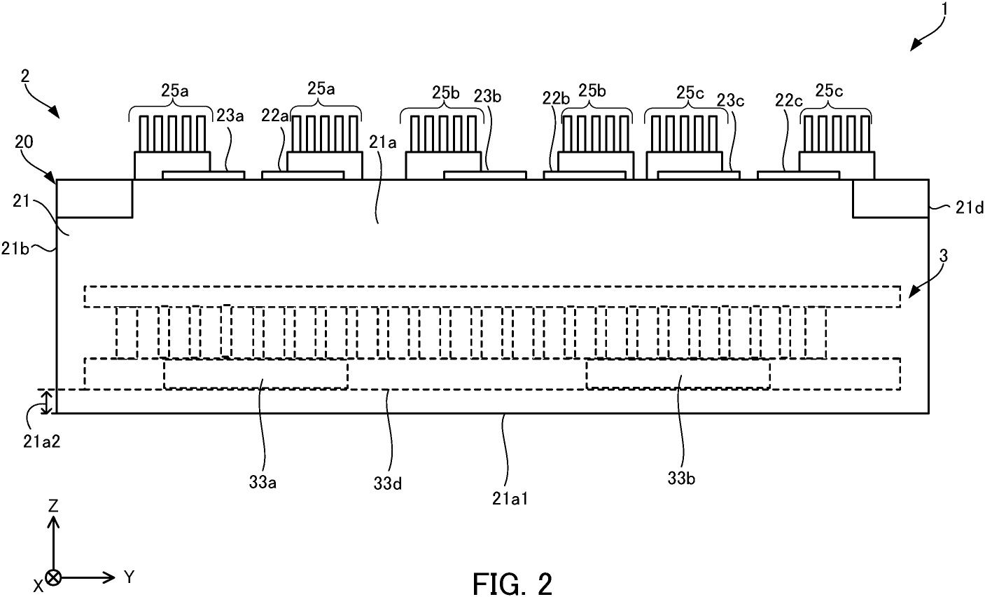

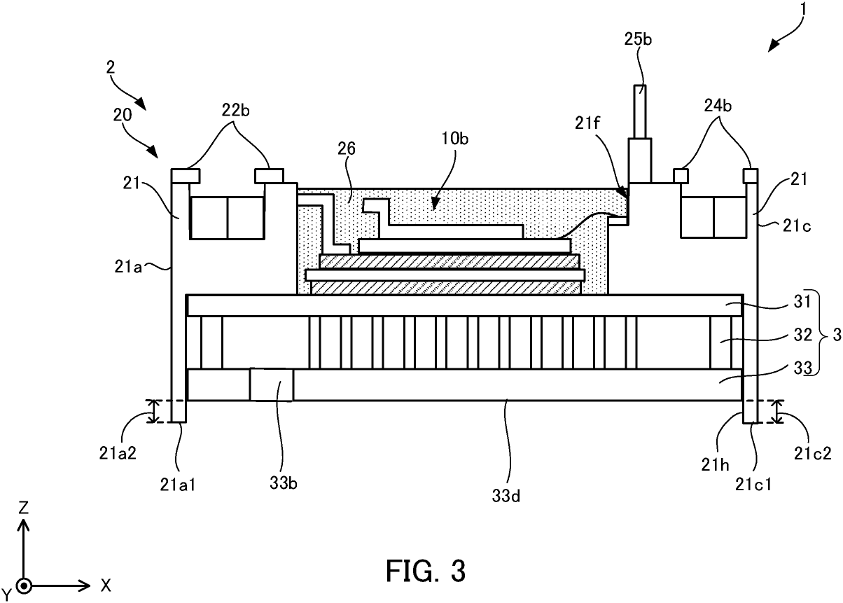

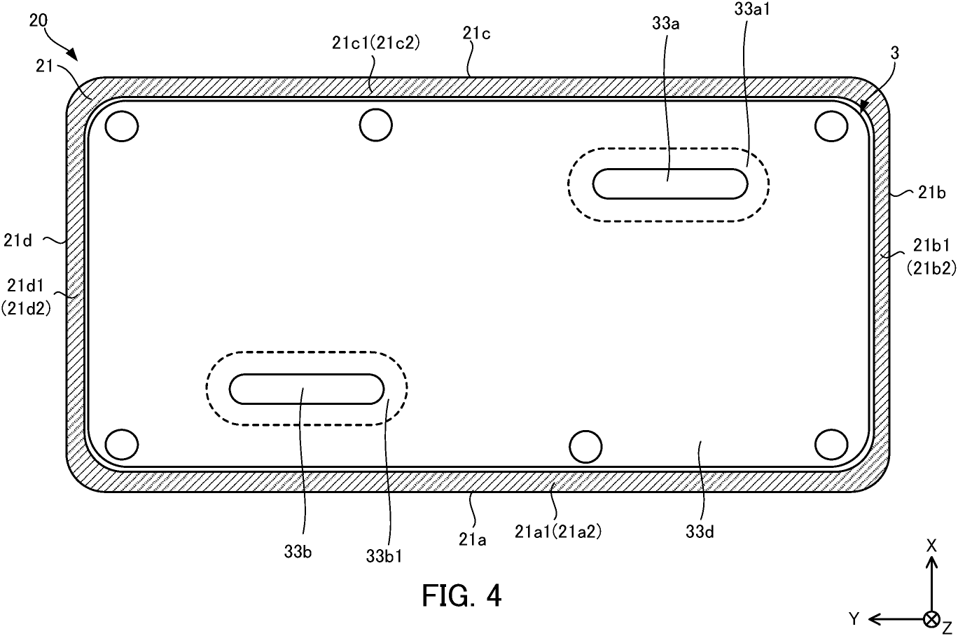

The semiconductor device 1 according to a first embodiment will now be described with reference to FIG. 1 to FIG. 4. FIG. 1 is a plan view of the semiconductor device according to the first embodiment, and FIG. 2 is a side view of the semiconductor device according to the first embodiment. FIG. 3 is a cross-sectional view of the semiconductor device according to the first embodiment, and FIG. 4 is a rear view of the semiconductor device according to the first embodiment. Note that FIG. 2 is a side view of the Y-Z plane in FIG. 1 in the X direction. FIG. 3 is a cross-sectional view taken along a dot-dash line Y-Y in FIG. 1. FIG. 4 is a view of the rear side of the semiconductor device 1 when the semiconductor device 1 in FIG. 1 has been rotated about a center line that passes through the centers of outer walls 21a and 21c.

The semiconductor device 1 includes a semiconductor module 2 and a cooling device 3. The semiconductor module 2 includes semiconductor units 10a, 10b, and 10c and a housing 20 that houses the semiconductor units 10a, 10b, and 10c. The semiconductor units 10a, 10b, and 10c housed in the housing 20 are encapsulated by an encapsulating member 26. Also in the first embodiment, the housing 20 includes the cooling device 3. Note that the semiconductor units 10a, 10b, and 10c all have the same configuration. When no distinction is made between them, the semiconductor units 10a, 10b, and 10c are referred to as the “semiconductor units 10”. The semiconductor units 10 will be described in detail later.

The housing 20 includes an outer frame 21, first connection terminals 22a, 22b, and 22c, second connection terminals 23a, 23b, and 23c, a U-phase output terminal 24a, a V-phase output terminal 24b, a W-phase output terminal 24c, and control terminals 25a, 25b, and 25c.

The outer frame 21 is substantially rectangular when in plan view and is surrounded on four sides by outer walls 21a, 21b, 21c, and 21d. Note that the outer walls 21a and 21c are the long sides of the outer frame 21 and the outer walls 21b and 21d are the short sides of the outer frame 21. Corner portions where the outer walls 21a, 21b, 21c, and 21d are connected are not necessarily right-angled, and may be chamfered into rounded shapes as depicted in FIG. 1. A fastening hole 21i that passes through the outer frame 21 is formed at each corner portion of a front surface of the outer frame 21. Note that the fastening holes 21i formed at the corner portions of the outer frame 21 are formed in stepped portions below the front surface of the outer frame 21. Fastening holes 21i that pass through the outer frame 21 are also formed on the outer wall 21a and 21c -sides of the outer frame 21.

The outer frame 21 includes unit housing portions 21e, 21f, and 21g on the front surface along the outer walls 21a and 21c. The unit housing portions 21e, 21f, and 21g are rectangular in plan view. The semiconductor units 10a, 10b and 10c are housed in these unit housing portions 21e, 21f, and 21g, respectively. On a rear surface thereof, the outer frame 21 further includes a cooling housing portion 21h, which is surrounded on four sides by the outer walls 21a, 21b, 21c, and 21d. The cooling housing portion 21h is positioned below the unit housing portions 21e, 21f, and 21g (in the -Z direction) and communicates with the unit housing portions 21e, 21f, and 21g. The cooling device 3 is housed in the cooling housing portion 21h. The outer frame 21 is attached from above to the cooling device 3 on which the semiconductor units 10a, 10b, and 10c have been aligned in the Y direction on the front surface thereof. When the cooling device 3 is housed in this way in the outer frame 21, spacer portions 21a2, 21b2, 21c2 and 21d2 at lower end portions (in the -Z direction) of the outer walls 21a, 21b, 21c and 21d protrude in the -Z direction beyond the cooling device 3 (that is, beyond a bottom surface 33d of a cooling bottom plate 33, which will be described later). In other words, outer wall bottom portions 21a1, 21b1, 21c1, and 21d1, which are bottom surfaces of the lower end portions (in the -Z direction) of the outer walls 21a, 21b, 21c, and 21d, are positioned lower (that is, further in the -Z direction) than the cooling device 3 (specifically the bottom surface 33d of the cooling bottom plate 33). Note that the bottom surface 33d of the cooling device 3 is formed with an inlet 33a and an outlet 33b. The cooling device 3 will be described in detail later.

In plan view, the outer frame 21 has the unit housing portions 21e, 21f, and 21g sandwiched between the first connection terminals 22a, 22b, and 22c and the second connection terminals 23a, 23b, and 23c on one side and the U-phase output terminal 24a, the V-phase output terminal 24b, and the W-phase output terminal 24c on the other side. The outer frame 21 is provided with the first connection terminals 22a, 22b, and 22c and the second connection terminals 23a, 23b, and 23c on the outer wall 21a side. The outer frame 21 is provided with the U-phase output terminal 24a, the V-phase output terminal 24b, and the W-phase output terminal 24c on the outer wall 21c side. The outer frame 21 also houses nuts under openings for the first connection terminals 22a, 22b, and 22c and the second connection terminals 23a, 23b, and 23c, with the nuts facing the openings. In the same way, the outer frame 21 houses nuts under openings for the U-phase output terminal 24a, the V-phase output terminal 24b, and the W-phase output terminal 24c of the outer frame 21, with the nuts facing the openings. The outer frame 21 is additionally provided with the control terminals 25a, 25b, and 25c along +X direction-sides of the unit housing portions 21e, 21f, and 21g in plan view. In the illustrated configuration, the control terminals 25a, 25b, and 25c are each split into two sets of terminals.

The outer frame 21 includes the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c, and is integrally formed by injection molding using a thermoplastic resin. By doing so, the housing 20 is constructed. Examples thermoplastic resins include polyphenylene sulfide resin, polybutylene terephthalate resin, polybutylene succinate resin, polyamide resin, and acrylonitrile-butadiene-styrene resin.

The first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c are made of a metal with superior electrical conductivity. Example metals include copper, aluminum, and an alloy that has at least one of these metals as a main component. Surfaces of the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c may be subjected to a plating process.

The encapsulating member 26 may be a thermosetting resin. Example thermosetting resins include epoxy resin, phenolic resin, maleimide resin, and polyester resin. Epoxy resin is preferably used. In addition, a filler may be added to the encapsulating member 26. The filler is a ceramic that is electrically insulating but has high thermal conductivity.

In this configuration, the outer walls 21a, 21b, 21c, and 21d include the spacer portions 21a2, 21b2, 21c2, and 21d2. In particular, the spacer portions 21a2 and 21c2 are included at lower portions (in the -Z direction) corresponding to positions where the first connection terminals 22a, 22b, and 22c, the second connection terminals 23a, 23b, and 23c, the U-phase output terminal 24a, the V-phase output terminal 24b, and the W-phase output terminal 24c are exposed. This means that the creepage distance from each terminal to the cooling bottom plate 33 of the cooling device 3 increases in keeping with the height of the spacer portions 21a2 and 21c2 (see FIG. 3). This means that it is possible to electrically insulate the semiconductor device 1 reliably.

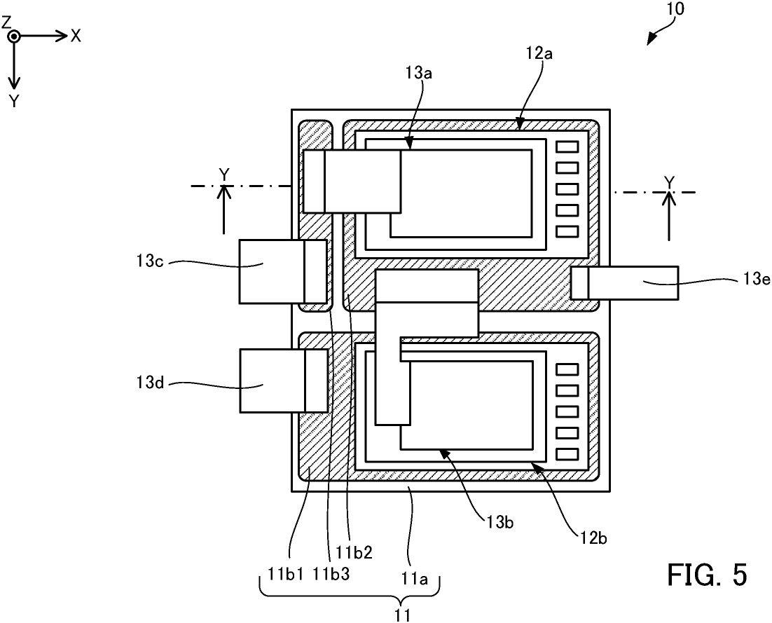

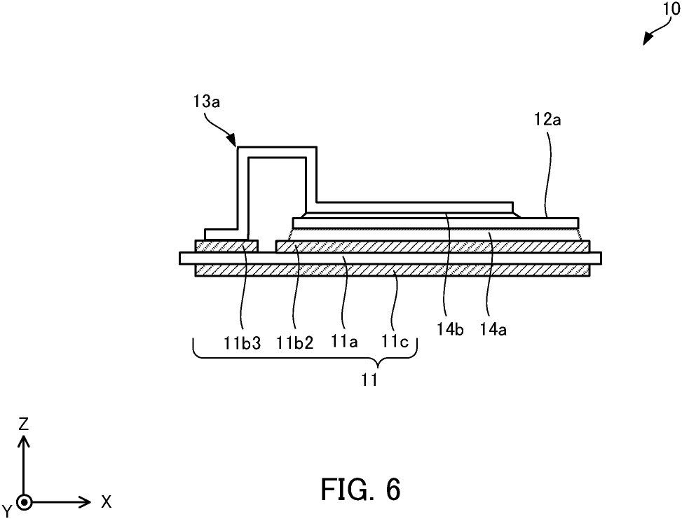

Next, the semiconductor units 10a, 10b, and 10c will be described with reference to FIGS. 5 and 6. FIG. 5 is a plan view of a semiconductor unit included in the semiconductor device according to the first embodiment, and FIG. 6 is a cross-sectional view of the semiconductor unit included in the semiconductor device according to the first embodiment. FIG. 6 is a cross-sectional view taken along a dot-dash line Y-Y in FIG. 5.

The semiconductor units 10 each include an insulated circuit board 11, semiconductor chips 12a and 12b, and lead frames 13a, 13b, 13c, 13d, and 13e. The insulated circuit board 11 includes an insulated board 11a, circuit patterns 11b1, 11b2, and 11b3, and a metal plate 11c. The insulated board 11a and the metal plate 11c are rectangular in plan view. Corners of the insulated board 11a and the metal plate 11c may be chamfered into rounded or beveled shapes. The metal plate 11c is smaller than the insulated board 11a in size in plan view, and is positioned on the inside of the insulated board 11a.

The insulated board 11a is made of an electrically insulating material that has superior thermal conductivity. The insulated board 11a is made of a ceramic or an insulating resin.

The circuit patterns 11b1, 11b2, and 11b3 are formed on a front surface of the insulated board 11a. The circuit patterns 11b1, 11b2, and 11b3 are made of metal with superior electrical conductivity. Example metals include copper, aluminum, or an alloy that has at least one of copper and aluminum as a main component.

The circuit pattern 11b1 is a region covering a +Y direction-side half of the front surface of the insulated board 11a, and occupies an entire region from the -X direction side to the +X direction side. The circuit pattern 11b2 occupies the -Y direction-side half of the front surface of the insulated board 11a. The circuit pattern 11b2 extends from the +X direction side to just before the -X direction side. The circuit pattern 11b3 occupies a region on the front surface of the insulated board 11a that is surrounded by the circuit patterns 11b1 and 11b2.

The circuit patterns 11b1, 11b2, and 11b3 described above are formed on the front surface of the insulated board 11a in the following manner. A metal plate is formed on the front surface of the insulated board 11a, and the metal plate is subjected to processing such as etching to obtain the circuit patterns 11b1, 11b2, and 11b3 that have predetermined shapes. Alternatively, the circuit patterns 11b1, 11b2, and 11b3 may be cut out from a metal plate in advance and then crimped onto the front surface of the insulated board 11a. Note that the depicted circuit patterns 11b1, 11b2, and 11b3 are mere examples. The number, shapes, sizes, and positions of the circuit patterns 11b1, 11b2, and 11b3 may be appropriately selected.

The metal plate 11c is formed on a rear surface of the insulated board 11a. The metal plate 11c is rectangular in shape. In plan view, the area of the metal plate 11c is smaller than the area of the insulated board 11a but larger than the area of the regions where the circuit patterns 11b1, 11b2, and 11b3 are formed. Corner portions of the metal plate 11c may be chamfered into rounded or beveled shapes. The metal plate 11c is formed with a smaller size than the insulated board 11a and on the entire surface of the insulated board 11a except for an edge portion. The metal plate 11c is made of a metal with superior thermal conductivity as a main component. Example metals include copper, aluminum, and an alloy that has at least one of these metals as a main component.

As examples of the insulated circuit board 11 with the configuration described above, it is possible to use a direct copper bonding (DCB) substrate, an active metal brazed (AMB) substrate, and a resin insulated substrate. The insulated circuit board 11 may be attached to the front surface of the cooling device 3 via a joining member (not illustrated). Heat generated by the semiconductor chips 12a and 12b may be transmitted via the circuit patterns 11b1 and 11b2, the insulated board 11a, and the metal plate 11c to the cooling device 3, where the heat is dissipated.

Joining members 14a and 14b are solder, brazing material, or sintered metal. Lead-free solder is used as the solder. As one example, lead-free solder has an alloy containing at least two of tin, silver, copper, zinc, antimony, indium, and bismuth as a main component. The solder may additionally contain additives. Example additives include nickel, germanium, cobalt, and silicon. Solder that contains additives has improved wettability, gloss, and bonding strength, which may improve reliability. Example brazing materials have at least one of aluminum alloy, titanium alloy, magnesium alloy, zirconium alloy, and silicon alloy as a main component. The insulated circuit board 11 may be joined to the cooling device 3 by brazing using a joining member like those described above. As one example, sintered metal has silver and silver alloy as a main component. Alternatively, the joining member may be a thermal interface material. Thermal interface materials are adhesives including elastomer sheets, room temperature vulcanization (RTV) rubber, gels, phase change materials, and the like. Attaching the semiconductor units 10 to the cooling device 3 via a brazing material or a thermal interface material like those described above improves the dissipation of heat by the semiconductor units 10.

The semiconductor chips 12a and 12b include power device elements made of silicon, silicon carbide, or gallium nitride. As one example, the thickness of the semiconductor chips 12a and 12b is at least 40 µm but not greater than 250 µm. The power device elements are reverse-conducting insulated gate bipolar transistors (RC-IGBT). An RC-IGBT has the functions of both an IGBT, which is a switching element, and a freewheeling diode (FWD), which is a diode element. A control electrode (gate electrode) and an output electrode (source electrode) are provided on front surfaces of the semiconductor chips 12a and 12b of this type. Input electrodes (collector electrodes) are provided on rear surfaces of the semiconductor chips 12a and 12b.

In place of RC-IGBT, the semiconductor chips 12a and 12b may each use a pair of a switching element and a diode element. As examples, the switching elements are IGBTs and power MOSFETs (Metal Oxide Semiconductor Field Effect Transistors). As one example, the semiconductor chips 12a and 12b of this type are equipped with a drain electrode (or collector electrode) as a main electrode on a rear surface and a control electrode and a gate electrode and source electrode (or emitter electrode) as main electrodes on a front surface.

As examples, the diode elements are free wheeling diodes (FWD), such as Schottky Barrier diodes (SBD) or P-intrinsic-N (PiN) diodes. The semiconductor chips 12a and 12b of this type are each equipped with a cathode electrode as a main electrode on the rear surface and an anode electrode as a main electrode on a front surface.

The rear surfaces of the semiconductor chips 12a and 12b are joined by the joining member 14a onto the predetermined circuit patterns 11b2 and 11b1. The joining member 14a is solder or sintered metal. Lead-free solder is used as the solder. As one example, lead-free solder has an alloy containing at least two of tin, silver, copper, zinc, antimony, indium, and bismuth as a main component. The solder may additionally contain additives. Example additives include nickel, germanium, cobalt and silicon. Solder that contains additives has improved wettability, gloss, and bonding strength, which may improve reliability. Example metals used as the sintered metal include silver and silver alloy.

The lead frames 13a, 13b, 13c, 13d, and 13e act as wiring that electrically connects the semiconductor chips 12a and 12b and the circuit patterns 11b1, 11b2, and 11b3. The semiconductor units 10 may be devices that configure a single-phase inverter circuit. The lead frame 13a connects an output electrode of the semiconductor chip 12a and the circuit pattern 11b3. The lead frame 13c is connected to the circuit pattern 11b3. The lead frame 13b connects an output electrode of the semiconductor chip 12b and the circuit pattern 11b2. The lead frame 13d is connected to the circuit pattern 11b1. The lead frame 13e is connected to the circuit pattern 11b2.

When the semiconductor units 10 of this type are housed in the unit housing portions 21e, 21f, and 21g, a second end portion of the lead frame 13e may serve as an output terminal of the semiconductor unit 10. That is, the second end portion of the lead frame 13e is connected to the U-phase output terminal 24a, the V-phase output terminal 24b, and the W-phase output terminal 24c.

A second end portion of the lead frame 13d may be a positive input terminal (or “P terminal”). A second end portion of the lead frame 13c may be a negative input terminal (or “N terminal”). That is, the second end portions of the lead frames 13c and 13d are connected to the first connection terminals 22a, 22b, and 22c and the second connection terminals 23a, 23b, and 23c, respectively. The control electrodes of the semiconductor chips 12a and 12b are directly connected by wires to the control terminals 25a, 25b, and 25c.

The lead frames 13a, 13b, 13c, 13d, and 13e are made of metal with superior electrical conductivity. Example metals include copper, aluminum, and an alloy containing at least one of these metals. To improve corrosion resistance, surfaces of the lead frames 13a, 13b, 13c, 13d, and 13e may be subjected to a plating process.

The lead frames 13a, 13b, 13c, 13d, and 13e are joined to the circuit patterns 11b1, 11b2, and 11b3 by joining members (not illustrated). The joining members may be the solder or sintered metal described earlier. Alternatively, the lead frames 13a, 13b, 13c, 13d, and 13e may be joined to the circuit patterns 11b1, 11b2, and 11b3 by laser welding or ultrasonic welding, for example. The lead frames 13a and 13b are joined via the joining member 14b to the output electrodes of the semiconductor chips 12a and 12b. The joining member 14b is made of the same material as the joining member 14a.

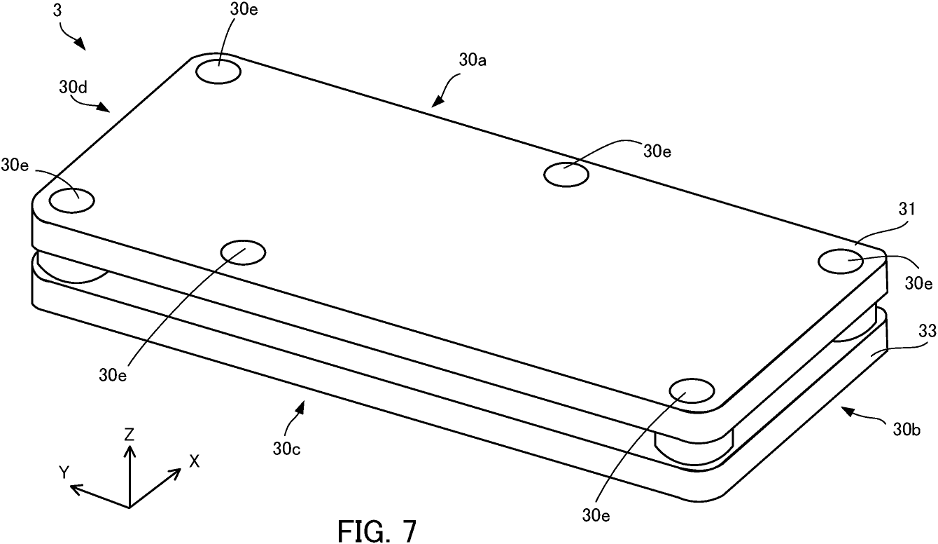

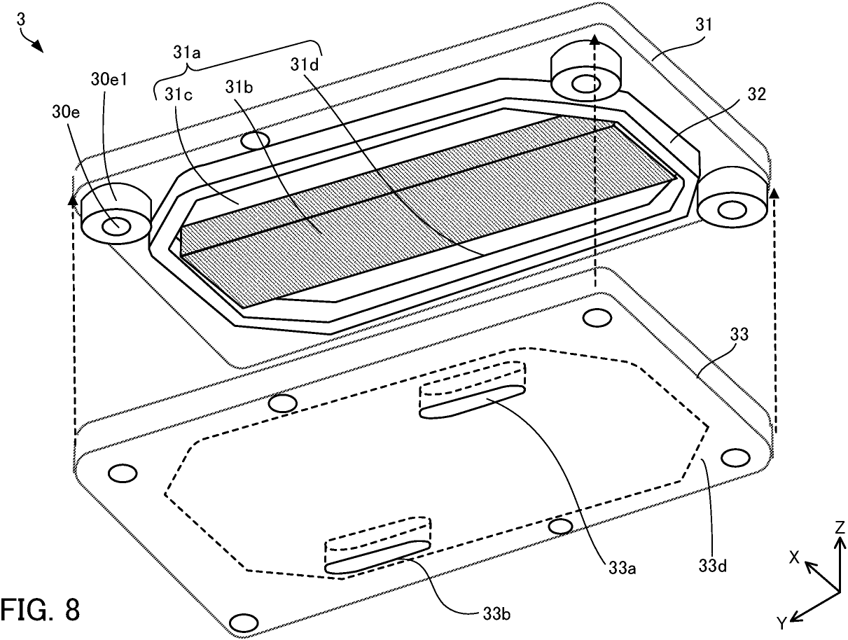

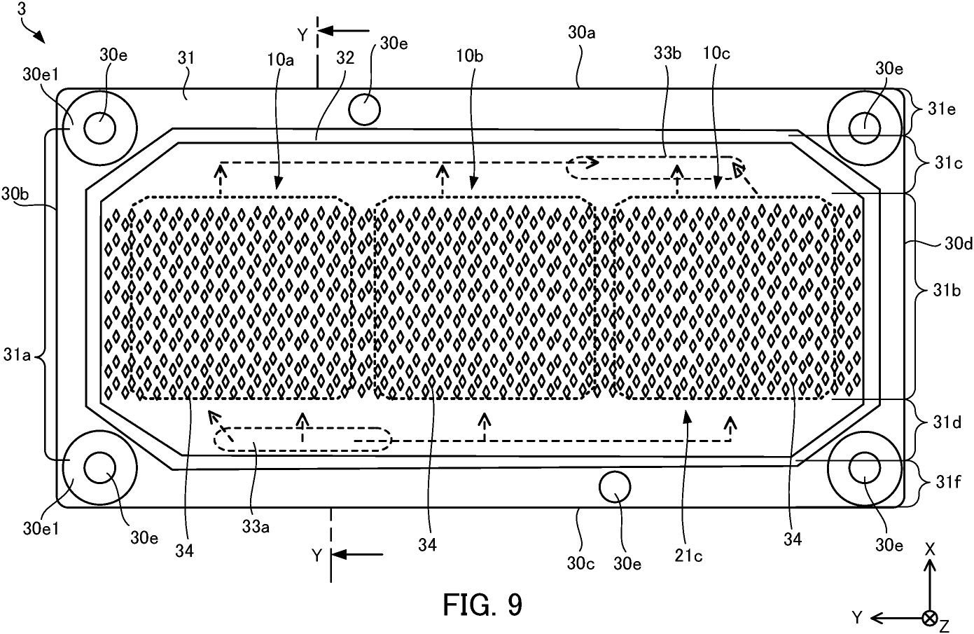

Next, the cooling device 3 will be described with reference to FIGS. 7 to 9. FIGS. 7 and 8 are perspective views of the cooling device included in the semiconductor device according to the first embodiment. FIG. 9 is a rear view of the cooling device included in the semiconductor device according to the first embodiment. FIG. 8 is a perspective view of a rear surface side of a top plate 31 of the cooling device 3. FIG. 9 is a plan view of the rear surface of the top plate 31 of the cooling device 3.

The cooling device 3 includes an inlet 33a that enables coolant to flow into the interior of the cooling device 3 and an outlet 33b that enables coolant that has passed through the interior to flow out. The cooling device 3 cools the semiconductor units 10 by discharging heat from the semiconductor units 10 via the coolant. Note that as examples, water, antifreeze (an aqueous solution of ethylene glycol), or long-life coolant (LLC) is used as the coolant.

In plan view, the cooling device 3 has a rectangular shape including long sides 30a and 30c and short sides 30b and 30d. The cooling device 3 is also formed with fastening holes 30e that pass through at least the four corners in plan view.

The three semiconductor units 10a, 10b, and 10c are mounted in a central portion of the front surface of the cooling device 3 (along the -Y direction) along the long sides 30a and 30c. Note that in FIG. 9, the mounting regions where the semiconductor units 10a, 10b, and 10c are disposed are indicated by broken lines. The number of semiconductor units 10 is not limited to three. So long as the semiconductor units 10 are disposed in a central portion (or “cooling region”, described later) of the cooling device 3, the sizes and disposed positions of the semiconductor units 10 are not limited to those in the present embodiment. The cooling device 3 may include a pump and a heat dissipating device (or “radiator”). The pump circulates the coolant by causing the coolant to flow into the inlet 33a of the cooling device 3 and causing coolant that has flowed out from the outlet 33b to flow back into the inlet 33a. The heat dissipating device dissipates heat, which has been transferred from the semiconductor units 10 to the coolant, to the outside.

The cooling device 3 includes the top plate 31, a side wall 32 that is ring-shaped and connected to a rear surface of the top plate 31, and a cooling bottom plate 33 that faces the top plate 31 and is connected to a rear surface of the side wall 32. In plan view, the top plate 31 has a rectangular shape surrounded by the long sides 30a and 30c and the short sides 30b and 30d, with the fastening holes 30e formed at the four corners. In plan view, corner portions of the top plate 31 may be chamfered into a rounded shape.

As depicted in FIG. 9, the top plate 31 is divided into a flow path region 31a and outer edge regions 31e and 31f. Note that as described later, the side wall 32 is connected to the rear surface of the top plate 31. The flow path region 31a is a region surrounded by the side wall 32. The flow path region 31a is further divided into a cooling region 31b and connecting regions 31c and 31d that are parallel with the long sides 30a and 30c. The cooling region 31b is a central rectangular region that is parallel to the long sides 30a and 30c (that is, the length direction) of the top plate 31. The plurality of semiconductor units 10 are disposed in a row along the Y direction in this cooling region 31b on a front surface of the top plate 31. The front surface of the top plate 31 on which the semiconductor units 10 are mounted is flat and does not have any stepped parts in the thickness direction (Z direction), and therefore forms a single plane.

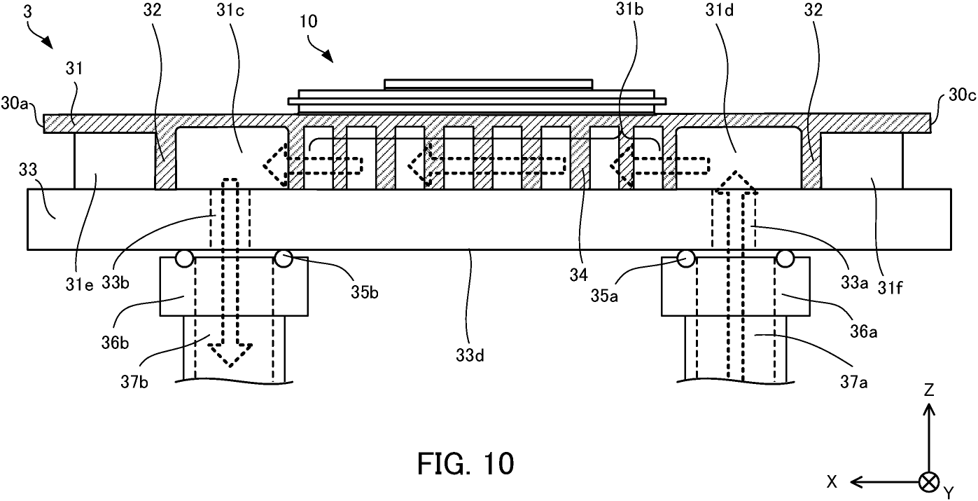

A plurality of heat dissipating fins 34 are formed on the cooling region 31b on the rear surface of the top plate 31. As one example, the thickness (that is, the length in the Z direction) of the top plate 31 is at least 2.0 mm but not greater than 5.0 mm. The plurality of heat dissipating fins 34 extend to connect the cooling region 31b on the rear surface of the top plate 31 and the cooling bottom plate 33. The height (that is, the length in the Z direction) of the plurality of heat dissipating fins 34 is at least 1.5 mm but not greater than 15.0 mm. The height is more preferably at least 2.0 mm but not greater than 12.0 mm. Note that FIG. 9 depicts the heat dissipating fins 34 in plan view, and FIG. 10 described later depicts the heat dissipating fins 34 in side view. However, FIG. 10 depicts the heat dissipating fins 34 schematically and does not necessarily match FIG. 9. In the cooling region 31b, the number of heat dissipating fins 34 disposed along the long sides 30a and 30c is greater than the number of heat dissipating fins 34 disposed along the short sides 30b and 30d. The cooling region 31b includes a region in which the heat dissipating fins 34 are provided and flow paths formed between the heat dissipating fins 34. Note that the gaps between adjacent heat dissipating fins 34 may be narrower than the width of the heat dissipating fins 34 themselves. The heat dissipating fins 34 have upper and lower ends in the ±Z direction. Upper ends of the heat dissipating fins 34 are thermally and mechanically connected to the rear surface of the top plate 31. The lower ends of the heat dissipating fins 34 are thermally and mechanically connected to a front surface of the cooling bottom plate 33 (that is, inside the cooling device 3) . The upper ends of the heat dissipating fins 34 may be integrally constructed with the top plate 31. That is, the heat dissipating fins 34 may integrally protrude in the -Z direction from the rear surface of the top plate 31. On the other hand, the lower ends of the heat dissipating fins 34 may be attached by brazing or the like to the front surface of the cooling bottom plate 33 (that is, inside the cooling device 3). The direction in which the heat dissipating fins 34 extend in the Z direction is substantially perpendicular to the respective main surfaces of the top plate 31 and the cooling bottom plate 33. The heat dissipating fins 34 may be pin fins. Each of the plurality of heat dissipating fins 34 is quadrangular in cross-section parallel to the main surface of the top plate 31. In FIG. 9, the heat dissipating fins 34 are formed in rhombus shapes. By doing so, it is possible to increase the surface area of the heat dissipating fins 34 that comes into contact with the coolant compared to a case where the heat dissipating fins 34 are circular in cross section, which means heat is dissipated with greater efficiency.

Also, the plurality of heat dissipating fins 34 may be disposed in the cooling region 31b of the top plate 31 so that when coolant flows into the cooling region 31b, none of the sides of the quadrangular shape of the fins is perpendicular to the main flow direction of the coolant in the cooling region 31b. In the present embodiment, the main flow direction of the coolant in the cooling region 31b is the X direction (that is, a direction that is parallel to the short sides 30b and 30d). The plurality of heat dissipating fins 34 are disposed in the cooling region 31b so that none of the sides of the quadrangular shape are perpendicular to the X direction. In more detail, the plurality of heat dissipating fins 34 are disposed so that none of the sides of the quadrangular shape is perpendicular to the X direction, one diagonal is parallel to the Y direction (that is, the long sides 30a and 30c) and the other diagonal is parallel to the X direction. Alternatively, the plurality of heat dissipating fins 34 may be disposed so that none of the sides of the rectangular shape are perpendicular to the X direction, one diagonal is inclined with respect to the Y direction, and the other diagonal is inclined with respect to the X direction. Compared to a configuration where the plurality of heat dissipating fins 34 are disposed in the cooling region 31b so that one side of the rectangular shape is perpendicular to the flow direction described above, all of the configurations described above are capable of reducing the drop in flow velocity of the coolant flowing through the cooling region 31b, which means heat is dissipated with greater efficiency.

On the X-Y plane depicted in FIG. 9, the heat dissipating fins 34 have rhombus shapes that are longer in the direction of the short sides 30b and 30d than in the direction of the long sides 30a and 30c. Note that the cross-sectional form of the plurality of heat dissipating fins 34 may be polygonal, for example, square. Alternatively, each of the plurality of heat dissipating fins 34 may be round, for example, a perfect circle, in cross-section. The plurality of heat dissipating fins 34 may be arranged in a predetermined pattern in the cooling region 31b. The plurality of heat dissipating fins 34 are disposed in a staggered arrangement as depicted in FIG. 9. The plurality of heat dissipating fins 34 may have a square arrangement in the cooling region 31b.

The connecting regions 31c and 31d are regions that are adjacent to both sides of the cooling region 31b on the top plate 31 and extend along the cooling region 31b. Accordingly, the connecting regions 31c and 31d are regions from the cooling region 31b to (the long side 30a and the long side 30c-sides of) the side wall 32. In the configuration in FIG. 9, the connecting regions 31c and 31d are trapezoidal. Note that as examples, depending on the range surrounded by the side wall 32, the connecting regions 31c and 31d may be rectangular, semicircular, or mountain-like shapes with a plurality of peaks. Corner portions of the connecting regions 31c and 31d may be chamfered into rounded shapes that are curved in plan view. This is performed to round any joins in the side wall 32 that constructs the connecting regions 31c and 31d. The coolant passing through the connecting regions 31c and 31d may flow easily at the rounded corner portions without collecting at the corner portions. By doing so, it is possible to prevent corrosion at the corner portions. The connecting regions 31c and 31d do not need to be symmetrical. Although described in detail later, the outlet 33b and the inlet 33a are formed at positions near the short sides 30b and 30d respectively corresponding to the connecting regions 31c and 31d. The outlet 33b and the inlet 33a are formed in central portions of the connecting regions 31c and 31d in the X direction. The connecting regions 31c and 31d may have shapes that make it easier for the coolant to flow out of and into the outlet 33b and the inlet 33a. As one example, the connecting region 31c may have a shape that narrows toward the outlet 33b so as to force the coolant into the outlet 33b.

The outer edge regions 31e and 31f are regions of the top plate 31 outside the flow path region 31a (that is, the cooling region 31b and the connecting regions 31c and 31d) . That is, in plan view, the outer edge regions 31e and 31f are regions from the side wall 32 of the top plate 31 to outer edges of the top plate 31. The fastening holes 30e described above and fastening reinforcing portions 30e1 are formed in the outer edge regions 31e and 31f.

The side wall 32 is formed on the rear surface of the top plate 31 in a ring shape so as to surround the cooling region 31b and the connecting regions 31c and 31d. An upper end of the side wall 32 in the +Z direction is attached to the rear surface of the top plate 31. A lower end of the side wall 32 in the -Z direction is attached to the front surface of the cooling bottom plate 33. In the configuration in FIG. 9, the side wall 32 has six sides including parts along the cooling region 31b parallel to the short sides 30b and 30d, parts along the connecting regions 31c and 31d parallel to the long sides 30a and 30c, and parts that connect the above parts. Corner portions at joins on the inside of the ring-shaped side wall 32 may be chamfered into rounded shapes. Provided that the cooling region 31b, which is rectangular in plan view, and the connecting regions 31c and 31d on both sides of the cooling region 31b may be accommodated, the side wall 32 does not need to be constructed of six sides. The height (that is, the length in the Z direction) of the side wall 32 corresponds to the height of the plurality of heat dissipating fins 34, and as one example is at least 1.5 mm but not greater than 15.0 mm. The height is more preferably at least 2.0 mm but not greater than 12.0 mm. The thickness (that is, the length in the X direction) of the side wall 32 is a sufficient thickness for making the cooling device 3 sufficiently strong when the side wall 32 is sandwiched between the top plate 31 and the cooling bottom plate 33 as described later without causing a drop in cooling performance. As one example, the thickness is at least 1.0 mm but not greater than 3.0 mm.

Also, on the rear surface of the top plate 31 (that is, inside the cooling device 3), the fastening reinforcing portions 30e1 may be formed around the fastening holes 30e. Each fastening reinforcing portion 30e1 is a screw frame formed with a through hole corresponding to a fastening hole 30e. The side wall 32 is interposed between the top plate 31 and the cooling bottom plate 33 and provides the cooling device 3 with sufficient strength. To do so, the height of the fastening reinforcing portions 30e1 is substantially equal to the height of the side wall 32. The width of each fastening reinforcing portion 30e1 (that is, the length in the radial direction from the center of the fastening hole 30e in plan view) is at least 0.7 times but not greater than 2.0 times the diameter of the fastening hole 30e.

The cooling bottom plate 33 is a flat plate and has the same shape as the top plate 31 in plan view. That is, in plan view, the cooling bottom plate 33 has a rectangular shape surrounded on four sides by long sides and short sides, with fastening holes corresponding to the top plate 31 formed at the four corners. Corner portions of the cooling bottom plate 33 may also be chamfered into rounded shapes. The cooling bottom plate 33 has a front surface and the bottom surface 33d that are parallel to each other. The expressions “front surface” and “bottom surface 33d” of the cooling bottom plate 33 here refer to respective main surfaces and exclude projections, such as spacer portions described later, depressions, and through-holes. Alternatively, the expressions “front surface” and “bottom surface 33d” of the cooling bottom plate 33 may refer to parts that face the mounting regions where the semiconductor units 10a, 10b, and 10c are respectively mounted. In the present embodiment, the bottom surface 33d of the cooling bottom plate 33 is a flat surface without any stepped parts, and therefore lies on a single plane. The bottom surface 33d of the cooling bottom plate 33 and the front surface of the top plate 31 may be parallel. The bottom surface 33d of the cooling bottom plate 33 is provided with the inlet 33a and the outlet 33b through which the coolant flows in and out. Note that sealing regions 33a1 and 33b1 are provided around the inlet 33a and the outlet 33b of the bottom surface 33d of the cooling bottom plate 33 so as to surround the inlet 33a and the outlet 33b. The sealing regions 33a1 and 33b1 will be described later. The inlet 33a is formed close to the long side 30c corresponding to the connecting region 31d, and close to the short side 30b. The outlet 33b is formed close to the long side 30a corresponding to the connecting region 31c and close to the short side 30d. That is, the inlet 33a and the outlet 33b are formed at positions that have point symmetry with respect to a center position on the bottom surface 33d of the cooling bottom plate 33. When this cooling bottom plate 33 is connected to the side wall 32, the fastening reinforcing portions 30e1 become connected to peripheries of the fastening holes provided in the cooling bottom plate 33. The cooling bottom plate 33 is formed with a thickness that does not cause a drop in cooling performance but provides the cooling device 3 as a whole with sufficient strength. The cooling bottom plate 33 is also sufficiently strong to attach pipes to the inlet 33a and the outlet 33b, as will be described later. To do so, the thickness of the cooling bottom plate 33 is at least 1.0 times but not greater than 5.0 times the thickness of the top plate 31. More preferably, the thickness is at least 2.0 times but not greater than 3.0 times the thickness of the top plate 31. As one example, the thickness of the cooling bottom plate 33 is preferably at least 2.0 mm but not greater than 10.0 mm.

The flow path region 31a surrounded by the top plate 31, the side wall 32, and the cooling bottom plate 33 is configured inside the cooling device 3 configured as described above. The flow path region 31a is further divided into the cooling region 31b and the connecting regions 31c and 31d. The plurality of heat dissipating fins 34, which connect the top plate 31 and the cooling bottom plate 33, extend in the cooling region 31b. The connecting regions 31c and 31d are constructed by the top plate 31, the side wall 32, and the cooling bottom plate 33. The connecting region 31d is connected to the cooling region 31b. Coolant that has entered via the inlet 33a flows from the connecting region 31d into the cooling region 31b. The connecting region 31c is connected to the cooling region 31b. Coolant from the cooling region 31b flows into the connecting region 31c and out of the outlet 33b. Note that the flow of coolant through the cooling device 3 will be described later. Outer edge regions 31e and 31f of the cooling device 3 are constructed by the outside of the flow path region 31a of the top plate 31, the outside of the side wall 32, and the cooling bottom plate 33.

The cooling device 3 is constructed with a metal with superior thermal conductivity as a main component. Example metals include copper, aluminum, or an alloy containing at least one of copper and aluminum. To improve the corrosion resistance of the cooling device 3, a plating process may be performed. As examples, the plating material used here is nickel, nickel-phosphorus alloy, or nickel-boron alloy. The top plate 31 on which the plurality of heat dissipating fins 34 are formed is formed by forging or casting (die casting), for example. When forging is used, the top plate 31 on which the plurality of heat dissipating fins 34 and the side wall 32 are formed is obtained by pressing a block-shaped member, whose main component is the metal described above, using a mold to cause plastic deformation. When die casting is used, the top plate 31 on which the plurality of heat dissipating fins 34 and the side wall 32 are formed is obtained by pouring a molten diecast material into a predetermined mold, cooling the material, and then removing the molded material. An example of the diecast material used here is an aluminum-based alloy. Alternatively, the top plate 31 on which the plurality of heat dissipating fins 34 and the side wall 32 are formed may be formed by cutting a block-shaped member that has the metal described above as a main component.

The cooling bottom plate 33 is joined to the plurality of heat dissipating fins 34 and the side wall 32 on the top plate 31. This joining is achieved by brazing. Accordingly, a rear surface, which is an end portion of the side wall 32 that extends from a main surface (or “rear surface”) of the top plate 31, and end portions of the heat dissipating fins 34 become individually joined by brazing material to the front surface of the cooling bottom plate 33. When the top plate 31 is formed by casting, the brazing material used in the brazing process has a lower melting point than the melting point of the diecast material. One example of a brazing material is an alloy containing aluminum as a main component.

Note that the fastening reinforcing portions 30e1 may be formed separately to the top plate 31 and joined to the cooling bottom plate 33 by brazing. Also, in the present embodiment, a configuration is described in which a plurality of heat dissipating fins 34 are connected to the top plate 31. However, the present embodiment is not limited to this configuration and a plurality of heat dissipating fins 34 may be formed on a region of the cooling bottom plate 33 that corresponds to the cooling region 31b. This completes the description of how the cooling device 3 is obtained.

Next, the flow of coolant in the cooling device 3 will be described with reference to FIG. 10 (and FIG. 9). FIG. 10 depicts the flow of coolant in the cooling device included in the semiconductor device according to the first embodiment. Note that FIG. 10 is a cross-sectional view taken along the dot-dash line Y-Y in FIG. 9. FIG. 10 depicts only the cooling device 3 and omits the housing 20.

Inside the cooling device 3, the coolant is circulated as described earlier by a pump. To circulate the coolant, a distribution head 36a is attached to the inlet 33a via a ring-shaped rubber seal 35a in the sealing region 33a1, which surrounds the inlet 33a. A pipe 37a is attached to the distribution head 36a. Similarly, a distribution head 36b is attached to the outlet 33b via a ring-shaped rubber seal 35b in the sealing region 33b1, which surrounds the outlet 33b. A pipe 37b is attached to the distribution head 36b. The pump is connected to the pipes 37a and 37b. In plan view, the sealing regions 33a1 and 33b1 may be regions from the outer edges of the inlet 33a and the outlet 33b to a position at least 0.2 times but not greater than 2.0 times the width of the inlet 33a and the outlet 33b. Here, the “width” of the inlet 33a and the outlet 33b may be the length of a shortest distance that passes through the centers of gravity of the inlet 33a and the outlet 33b. As examples, the width of the inlet 33a and the outlet 33b may be the distance between the long sides when the inlet 33a and the outlet 33b are shaped as a rectangle or slot, may be the minor axis of an ellipse, or may be the diameter of a circle. In plan view, the sealing regions 33a1 and 33b1 may be regions that extend up to 20 mm from the outer edges of the inlet 33a and the outlet 33b, and are preferably regions that extend up to 10 mm from the outer edges of the inlet 33a and the outlet 33b.

As depicted in FIG. 9, the coolant that has flowed in from the inlet 33a flows into the connecting region 31d and spreads out inside the connecting region 31d. The coolant that has flowed in from the connecting region 31d spreads out toward the short side 30b (in the Y direction) and also spreads out toward the long side 30a (in the X direction). When the coolant flows in from the inlet 33a, the coolant also spreads directly toward the long side 30a (in the X direction). By doing so, the coolant flows to the entire side portion of the cooling region 31b that faces the long side 30c.

As depicted in FIG. 10, the coolant that has flowed to the side portion (on the long side 30c-side) of the cooling region 31b flows between the plurality of heat dissipating fins 34 toward the long side 30a-side (that is, the X direction). Heat from the semiconductor units 10, which have heated up, is transferred via the top plate 31 to the plurality of heat dissipating fins 34. When passing between the plurality of heat dissipating fins 34, the coolant receives this heat from the plurality of heat dissipating fins 34. This facilitates transmission of the heat of the semiconductor units 10 to the plurality of heat dissipating fins 34. A large amount of heat may be transmitted to the coolant that passes through the gaps between the heat dissipating fins 34, which improves the cooling performance.

As depicted in FIG. 9 (and FIG. 10), the coolant that has been heated in this way flows from the side portion of the cooling region 31b that faces the long side 30a into the connecting region 31c, and then flows through the outlet 33b to the outside. The coolant that flows out contains heat that has been transmitted from the plurality of heat dissipating fins 34. The coolant that has flowed out is cooled by a separate heat dissipating device and is pumped back into the cooling device 3 from the inlet 33a. In this way, the semiconductor units 10 are cooled by expelling heat produced by the semiconductor units 10 to the outside through the circulation of the coolant through the cooling device 3.

As described above, the pipes 37a and 37b that enable the coolant to appropriately flow into and out of the inlet 33a and the outlet 33b are attached in a sealed manner to the bottom surface 33d of the cooling bottom plate 33 of the cooling device 3. When the bottom surface 33d of the cooling bottom plate 33 is damaged, especially the sealing regions around the inlet 33a and outlet 33b to which the pipes 37a, 37b are attached, the sealing is compromised. As a result, there is the risk of coolant leaking out from the inlet 33a and the outlet 33b.

For this reason, the outer frame 21 (that is, the outer walls 21a, 21b, 21c, and 21d) of the housing 20 of the semiconductor device 1 is provided with spacer portions 21a2, 21b2, 21c2, and 21d2 that protrude in the opposite direction to the semiconductor chips 12a and 12b beyond the bottom surface 33d of the cooling bottom plate 33. When the semiconductor device 1 is placed on an arbitrary placement surface for example, a gap is produced by the spacer portions 21a2, 21b2, 21c2, and 21d2 between the rear surface of the cooling device 3 (that is, the bottom surface 33d of the cooling bottom plate 33) and the placement surface. This means that the bottom surface 33d of the cooling bottom plate 33 does not directly touch the placement surface and is less likely to become damaged. This means that when the semiconductor device 1 is placed on a predetermined tray and packed in a box for shipment for example, damage to the rear surface of the cooling device 3 (that is, the bottom surface 33d of the cooling bottom plate 33) is prevented, so that at the shipping destination, sealing is maintained between the pipes 37a and 37b, which are attached to the cooling device 3 of the semiconductor device 1, and the inlet 33a and the outlet 33b of the cooling bottom plate 33. This prevents leaks of the coolant from the cooling device 3, suppresses a drop in the cooling performance of the cooling device 3, and enables the semiconductor units 10 to be appropriately cooled. As a result, it is possible to suppress any drop in reliability of the semiconductor device 1. For the semiconductor device 1, it is important to prevent damage to the sealing regions 33a1 and 33b1 around the inlet 33a and the outlet 33b. On the other hand, depending on the shapes and types of the pipes, the sealing regions 33a1 and 33b1 may extend in wide ranges around the inlet 33a and the outlet 33b. For this reason, by preventing the occurrence of damage to the entire rear surface of the cooling device 3, it is possible to cope with all types of pipes.

Note that the outer wall bottom portions 21a1, 21b1, 21c1, and 21d1 of the outer walls 21a, 21b, 21c, and 21d of the outer frame 21 may be parallel to the placement surface, or may be semicircular in cross section. Corner portions of the spacer portions 21a2, 21b2, 21c2, and 21d2 of the outer walls 21a, 21b, 21c, and 21d may also be chamfered into rounded or beveled shapes.

Next, various forms of spacer portions of the outer walls 21a, 21b, 21c, and 21d of the outer frame 21 of the semiconductor device 1 will be described. Unless otherwise specified, the modifications described below differ to the semiconductor device 1 of the first embodiment only in the spacer portions of the outer walls 21a, 21b, 21c, and 21d. Aside from the spacer portions, these modifications include the same component elements as the semiconductor device 1.

### Modification 1-1

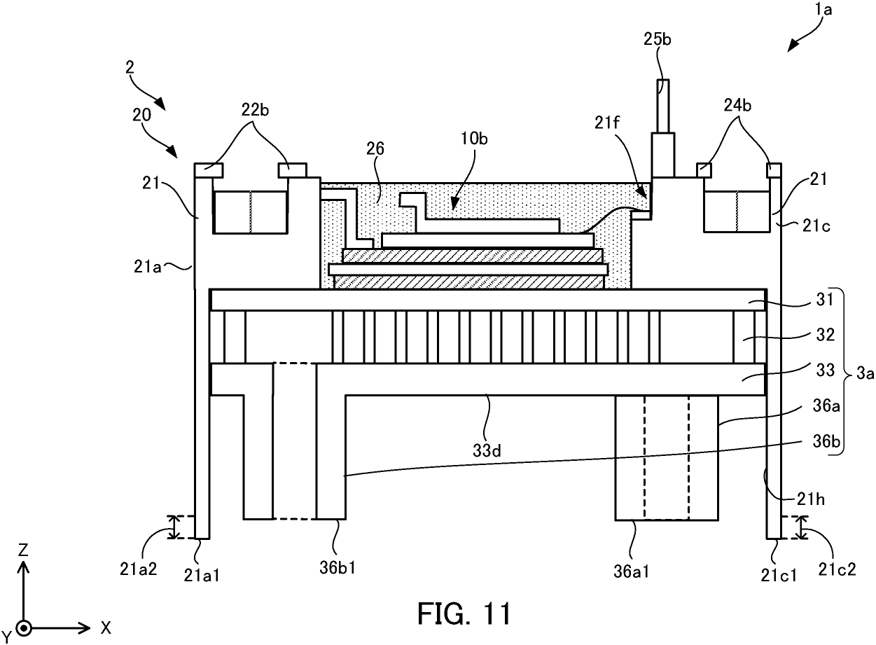

A semiconductor device that is a modification 1-1 of the first embodiment will now be described with reference to FIG. 11. FIG. 11 is a cross-sectional view of a semiconductor device according to the modification 1-1 of the first embodiment. On a cooling device 3a included in a semiconductor device 1a, the distribution heads 36a and 36b are connected to the inlet 33a and the outlet 33b on the cooling bottom plate 33. The distribution heads 36a, 36b are formed on the bottom surface 33d of the cooling bottom plate 33 with first ends that pass through the inlet 33a and the outlet 33b and other ends (or “head bottom surfaces 36a1 and 36b1”) that extend in the opposite direction to the semiconductor chips 12a and 12b. The distribution heads 36a and 36b may be integrally formed with the cooling device 3a (that is, the cooling bottom plate 33). In this configuration, the outer walls 21a, 21b, 21c, and 21d of the outer frame 21 surround the four sides of the side wall 32 of the cooling device 3a and also the distribution heads 36a and 36b. In addition, the outer walls 21a, 21b, 21c, and 21d are provided with the spacer portions 21a2, 21b2, 21c2, and 21d2 that protrude downward (in the -Z direction) beyond the head bottom surfaces 36a1 and 36b1 of the distribution heads 36a and 36b.

When this semiconductor device 1a is placed on an arbitrary placement surface, a gap is produced by the spacer portions 21a2, 21b2, 21c2, and 21d2 between the head bottom surfaces 36a1 and 36b1 of the distribution heads 36a and 36b and the placement surface. This means that the head bottom surfaces 36a1 and 36b1 of the distribution heads 36a and 36b will not directly touch the placement surface and are less likely to be damaged. A distribution joint connected to a pump is connected via rubber seals to the distribution heads 36a and 36b. When the head bottom surfaces 36a1 and 36b1 of the distribution heads 36a and 36b suffer damage, favorable sealing is not maintained between the distribution heads 36a and 36b and the distribution joint. In the semiconductor device 1a, the head bottom surfaces 36a1 and 36b1 of the distribution heads 36a and 36b attached to the cooling device 3a are prevented from being damaged. This ensures that the seal between the distribution heads 36a, 36b and the distribution joint is maintained. Leaking of the coolant at the distribution heads 36a and 36b is therefore prevented, which makes it possible to suppress a drop in the cooling performance of the cooling device 3a and to appropriately cool the semiconductor units 10 (in FIG. 11, the semiconductor unit 10b). As a result, a drop in reliability for the semiconductor device 1a may be suppressed.

The semiconductor device 1a also includes spacer portions 21a2 and 21c2 on a lower portion (in the -Z direction) corresponding to positions where the first connection terminals 22a, 22b, and 22c, the second connection terminals 23a, 23b, and 23c, the U-phase output terminal 24a, the V-phase output terminal 24b, and the W-phase output terminal 24c are exposed. For the semiconductor device 1a, the creepage distance from each terminal to the cooling bottom plate 33 of the cooling device 3a is longer by the height of the distribution heads 36a and 36b (see FIG. 11) than the creepage distance in the semiconductor device 1 according to the first embodiment. This means that it is possible to electrically insulate the semiconductor device 1a more reliably.

### Modification 1-2

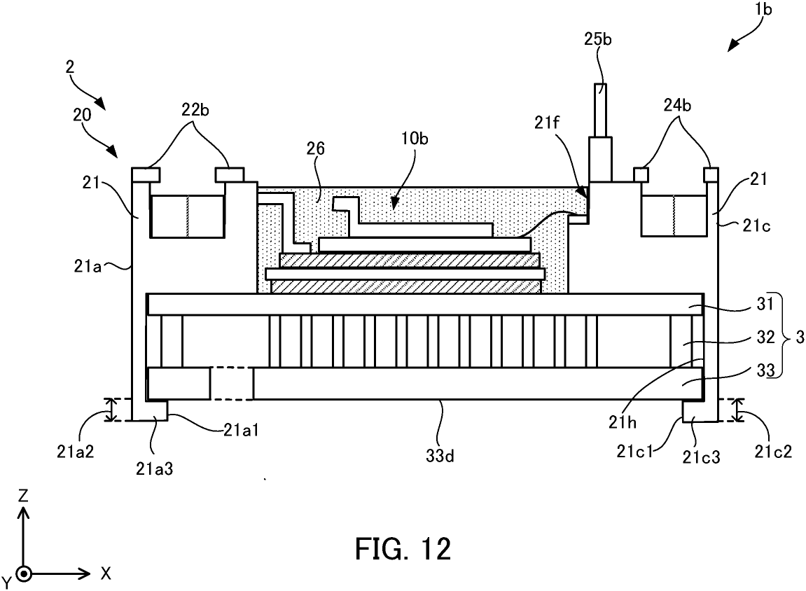

A semiconductor device that is a modification 1-2 of the first embodiment will now be described with reference to FIG. 12. FIG. 12 is a cross-sectional view of the semiconductor device according to the modification 1-2 of the first embodiment. Note that FIG. 12 is a cross-sectional view at a location corresponding to FIG. 3. The outer walls 21a, 21b, 21c, and 21d of the outer frame 21 included in a semiconductor device 1b include tabs that are bent inward from the position of the bottom surface 33d of the cooling bottom plate 33. Each tab that is bent in this way supports the cooling bottom plate 33. Note that FIG. 12 depicts tabs 21a3 and 21c3 that are bent inward at the outer walls 21a and 21c. In this configuration, the bending width (in FIG. 12, the length of the tabs 21a3 and 21c3 in the ±X direction) is set so that the fastening holes 21i of the cooling bottom plate 33 are not covered.

In this configuration, the thickness (height) of the tabs at the outer walls 21a, 21b, 21c, and 21d function as spacer portions. Note that the spacer portions 21a2 and 21c2 are depicted in FIG. 12. When the semiconductor device 1b is placed on a placement surface, the spacer portions (in FIG. 12, the spacer portions 21a2 and 21c2) described above produce a gap between the semiconductor device 1b and the placement surface. This means that the bottom surface 33d of the cooling bottom plate 33 does not directly touch the placement surface and is less likely to be damaged. The cooling device 3 is supported by the tabs of the outer walls 21a, 21b, 21c, and 21d. This protects the cooling device 3 when the semiconductor device 1b receives an external shock, and prevents the cooling device 3 from becoming separated.

In the semiconductor device 1b, the thickness of all of the outer walls 21a, 21b, 21c, and 21d of the outer frame 21 may be uniform. That is, the thickness of the outer walls 21a, 21b, 21c, and 21d of the outer frame 21 as far as the cooling device 3 and the thickness of the tabs are substantially the same. The thickness of the tabs on the outer walls 21a, 21b, 21c, and 21d of the outer frame 21 may also be made thicker than other regions to increase the height of the spacer portions.

The semiconductor device 1b may also include spacer portions 21a2 and 21c2 at lower portions (in the -Z direction) corresponding to positions where the first connection terminals 22a, 22b, and 22c, the second connection terminals 23a, 23b, and 23c, the U-phase output terminal 24a, the V-phase output terminal 24b, and the W-phase output terminal 24c are exposed. For the semiconductor device 1b of this configuration, the creepage distance from each terminal to the cooling bottom plate 33 of the cooling device 3 is longer by the length of the tabs 21a3 and 21c3 than the creepage distance in the semiconductor device 1 according to the first embodiment (see FIG. 12). This means that it is possible to electrically insulate the semiconductor device 1b more reliably.

### Modification 1-3

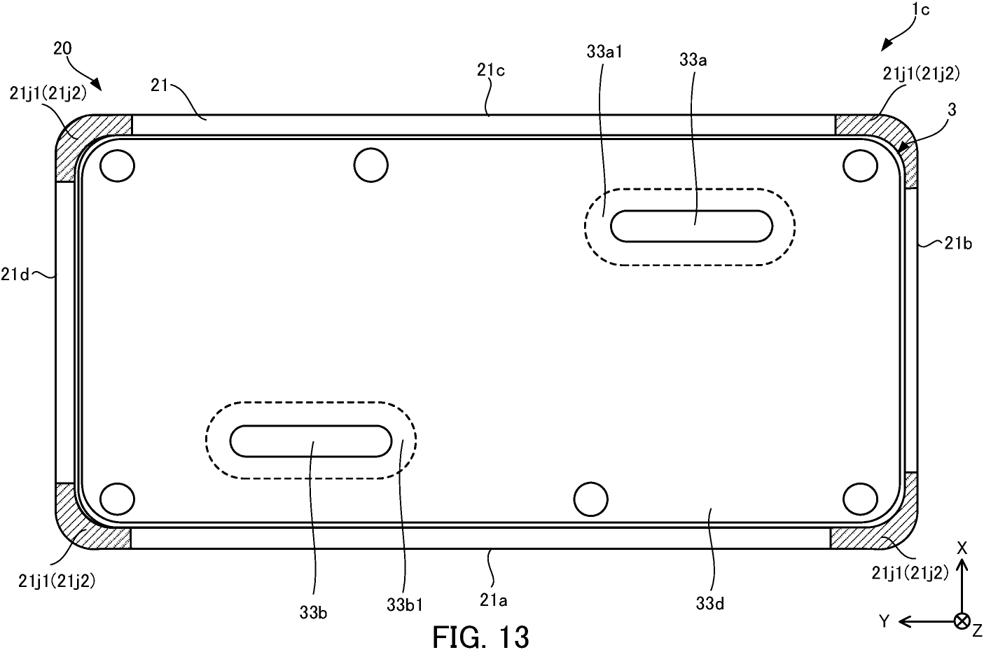

A semiconductor device that is a modification 1-3 of the first embodiment will now be described with reference to FIG. 13. FIG. 13 is a rear view of the semiconductor device according to the modification 1-3 of the first embodiment. Spacer portions 21j2 are provided at corner portions of the outer walls 21a, 21b, 21c, and 21d of the outer frame 21 of the semiconductor device 1c in plan view so as to cover parts of the outer peripheries of the fastening holes 21i that face the outer walls 21a, 21b, 21c, and 21d. That is, outer wall bottom portions 21j1 of the spacer portions 21j2 protrude below (that is, in the -Z direction) the bottom surface 33d of the cooling bottom plate 33.

When the semiconductor device 1c described above is placed on a placement surface, the spacer portions 21j2 at the four corner portions enable the semiconductor device 1c to stably sit on the placement surface with a gap produced in between. This means that the bottom surface 33d of the cooling bottom plate 33 does not directly touch the placement surface and is less likely to become damaged. Since the spacer portions 21j2 are provided so as to surround the fastening holes 21i, the fastening holes 21i are protected.

Note that for the semiconductor device 1c, so long as a gap is provided between the rear surface of the cooling device 3 (the bottom surface 33d of the cooling bottom plate 33) and the placement surface, it is sufficient to provide the spacer portions at at least a pair of diagonally opposite corners of the outer walls 21a, 21b, 21c, and 21d of the outer frame 21 that is rectangular in plan view. The semiconductor device 1c may also be provided with tabs like the modification 1-3.

### Modification 1-4

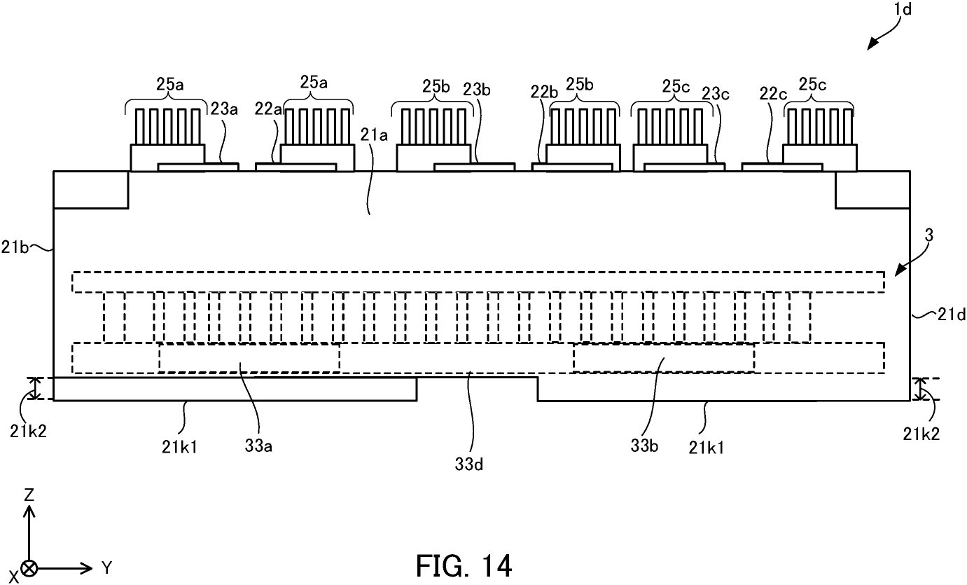

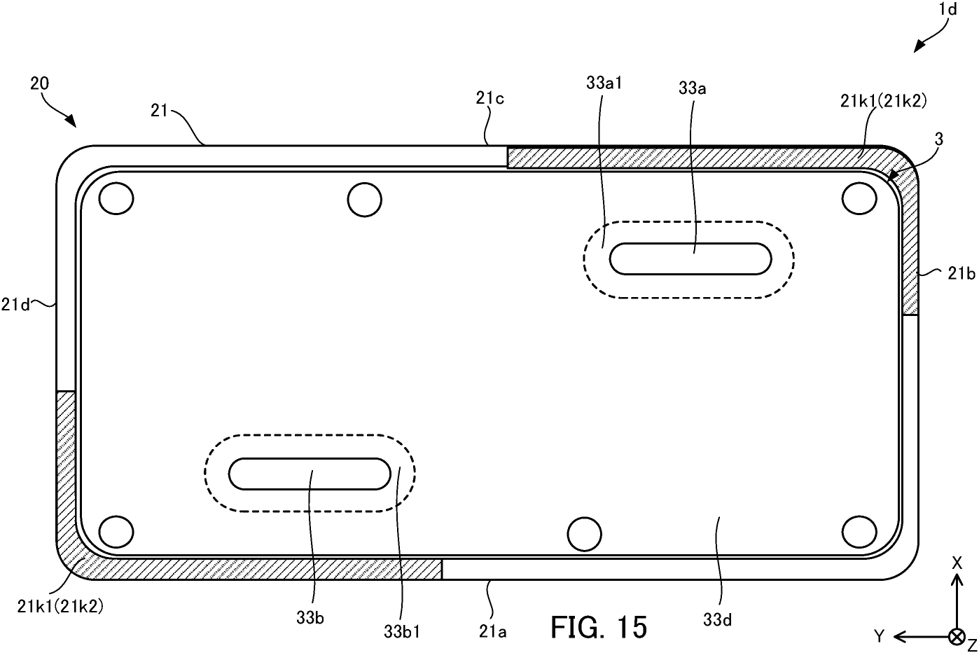

A semiconductor device that is a modification 1-4 of the first embodiment will now be described with reference to FIGS. 14 and 15. FIG. 14 is a side view of the semiconductor device of the modification 1-4 of the first embodiment, and FIG. 15 is a rear view of the modification 1-4 of the semiconductor device of the first embodiment. Note that the view of a semiconductor device 1d in FIG. 14 corresponds to the side view in FIG. 2.

Spacer portions 21k2 are provided on the outer walls 21a, 21b, 21c, and 21d of the outer frame 21 of the semiconductor device 1d so as to cover parts of the outer circumferences of the inlet 33a and the outlet 33b that face the outer walls 21a, 21b, 21c, and 21d. The spacer portions 21k2 are L-shaped in plan view, with corners near the fastening holes 21i. That is, outer wall bottom portions 21k1 of the spacer portions 21k2 protrude below (that is, in the -Z direction) the bottom surface 33d of the cooling bottom plate 33.

The inlet 33a and the outlet 33b are formed near diagonally opposite corner portions of the cooling bottom plate 33. The inlet 33a is provided in the vicinity of a corner portion of the cooling bottom plate 33 formed by the outer walls 21b and 21c, and the outlet 33b is provided in the vicinity of a corner portion formed by the outer walls 21a and 21d. It is sufficient for the spacer portion 21k2 to be provided at at least parts where the inlet 33a faces the outer walls 21c and 21b. In FIG. 15, the spacer portion 21k2 is longer than the parts where the outer circumference of the inlet 33a faces the outer walls 21c and 21b and is formed in an L shape. In the same way, the spacer portion 21k2 is longer than parts where the outer circumference of the outlet 33b faces the outer walls 21a and 21d, and is formed in an L shape.

When the semiconductor device 1d is placed on a placement surface, the spacer portions 21k2 at the corner portions that are L-shaped in plan view enable the semiconductor device 1d to stably sit on the placement surface with a gap produced in between. This means that the bottom surface 33d of the cooling bottom plate 33 does not directly touch the placement surface and is less likely to become damaged. Since the spacer portions 21k2 are provided so as to surround the inlet 33a and the outlet 33b, the inlet 33a and the outlet 33b are protected.

In the semiconductor device 1d, spacer portions may also be provided so as to cover parts of the outer peripheries of the fastening holes 21i that face the outer walls 21a, 21b, 21c, and 21d at other diagonally opposite corner portions (that is, upper left and lower right in FIG. 15) to the inlet 33a and outlet 33b. By doing so, it is possible to protect the fastening holes 21i at all four corners, not just the inlet 33a and the outlet 33b. The semiconductor device 1d may also be provided with tabs like the modification 1-3.

### Modification 1-5

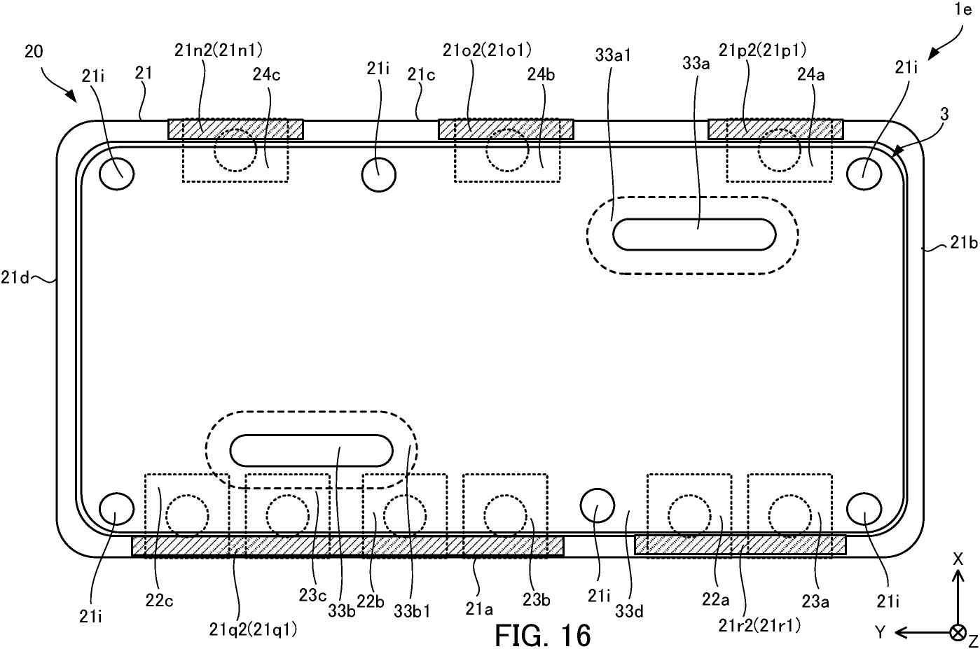

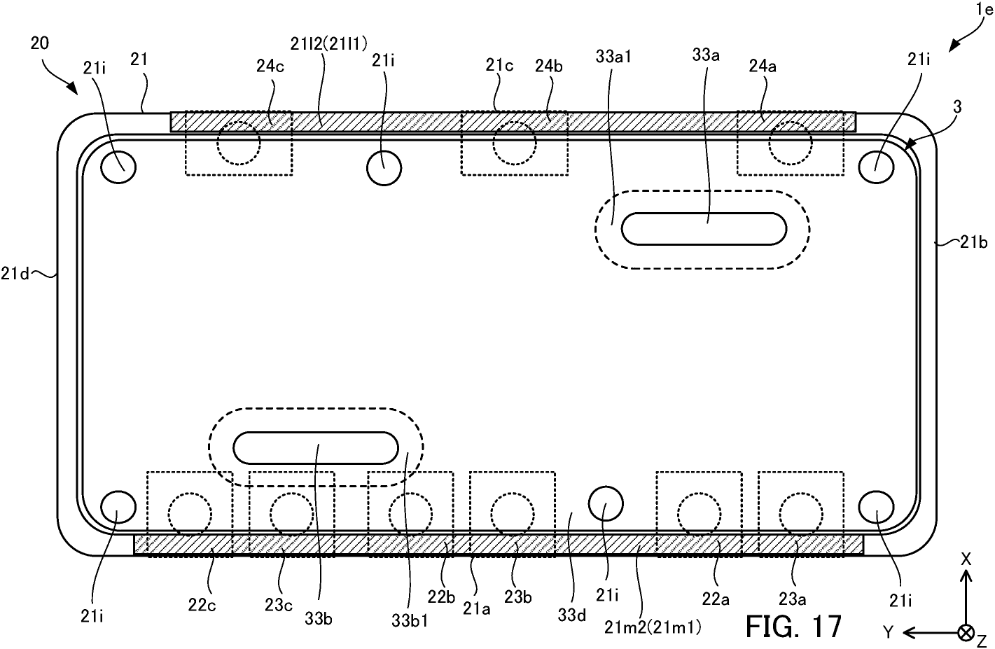

A semiconductor device that is a modification 1-5 of the first embodiment will now be described with reference to FIGS. 16 and 17. FIGS. 16 and 17 are rear views of the semiconductor device according to the modification 1-5 of the first embodiment. Note that in FIGS. 16 and 17, positions where the first connection terminals 22a, 22b, and 22c, the second connection terminals 23a, 23b, and 23c, the U-phase output terminal 24a, the V-phase output terminal 24b, and the W-phase output terminal 24c are exposed on the front surface when looking at a semiconductor device 1e from the rear surface are indicated by broken lines.

In the semiconductor device 1e depicted in FIG. 16, spacer portions are provided at parts of the outer walls 21a, 21b, 21c, and 21d of the outer frame 21 corresponding to positions where the first connection terminals 22a, 22b, and 22c, the second connection terminals 23a, 23b, and 23c, the U-phase output terminal 24a, the V-phase output terminal 24b, and the W-phase output terminal 24c are exposed.

That is, the outer wall 21c includes spacer portions 21n2, 21o2, and 21p2 at parts corresponding to the positions where the U-phase output terminal 24a, the V-phase output terminal 24b, and the W-phase output terminal 24c are exposed. Outer wall bottom portions 21n1, 21o1, and 21p1 of the spacer portions 21n2, 21o2, and 21p2 protrude below (that is, in the -Z direction) the bottom surface 33d of the cooling bottom plate 33.

The outer wall 21a includes a spacer portion 21q2 in which parts corresponding to the positions where the first connection terminals 22b and 22c and the second connection terminals 23b and 23c are exposed are connected. An outer wall bottom portion 21q1 of the spacer portion 21q2 protrudes below (that is, in the -Z direction) the bottom surface 33d of the cooling bottom plate 33.

The outer wall 21a also includes a spacer portion 21r2 in which parts corresponding to the positions where the first connection terminal 22a and the second connection terminal 23a are exposed are connected. An outer wall bottom portion 21r1 of the spacer portion 21r2 protrudes below (that is, in the -Z direction) the bottom surface 33d of the cooling bottom plate 33. Note that in the semiconductor device 1e depicted in FIG. 16, the outer wall 21a may include a spacer portion with unconnected parts corresponding to positions where the first connection terminals 22a, 22b, and 22c and the second connection terminals 23a, 23b, and 23c are exposed.

In the semiconductor device 1e, spacer portions do not need to be individually provided for terminals. As one example, as depicted in FIG. 17, the outer wall 21a of the semiconductor device 1e includes a spacer portion 21m2 in which parts corresponding to positions where the first connection terminals 22a, 22b, and 22c and the second connection terminals 23a, 23b, and 23c are exposed are connected. An outer wall bottom portion 21m1 of the spacer portion 21m2 protrudes below (that is, in the -Z direction) the bottom surface 33d of the cooling bottom plate 33. As depicted in FIG. 17, the outer wall 21c of the semiconductor device 1e includes a spacer portion 2112 in which parts corresponding to positions where the U-phase output terminal 24a, the V-phase output terminal 24b, and the W-phase output terminal 24c are exposed are connected. An outer wall bottom portion 21|1 of the spacer portion 21l2 protrudes below (that is, in the -Z direction) the bottom surface 33d of the cooling bottom plate 33.

When the semiconductor device 1e described above is placed on a placement surface, the spacer portions 21n2, 21o2, 21p2, 21q2, and 21r2, as well as the spacer portions 2112 and 21m2, enable the semiconductor device 1e to stably sit on the placement surface with a gap produced in between. This means that the bottom surface 33d of the cooling bottom plate 33 does not directly touch the placement surface and is less likely to be damaged. The semiconductor device 1e may also include tabs like the modification 1-3.

The outer walls 21a, 21b, 21c, and 21d also include spacer portions 21n2, 21o2, 21p2, 21q2, and 21r2 as well as the spacer portions 21l2 and 21m2 in which parts corresponding to the positions where the first connection terminals 22a, 22b, and 22c, the second connection terminals 23a, 23b, and 23c, the U-phase output terminal 24a, the V-phase output terminal 24b, and the W-phase output terminal 24c are exposed. This means that the creepage distance from each terminal to the cooling bottom plate 33 of the cooling device 3 increases in keeping with the heights of the spacer portions 21n2, 21o2, 21p2, 21q2, and 21r2 as well as the spacer portions 21l2 and 21m2. This means that it is possible to electrically insulate the semiconductor device 1e more reliably.

By including spacer portions (whose reference numerals are omitted here) at a lower portion (in the -Z direction) corresponding to the respective terminals like in the first embodiment and the modifications 1-1, 1-2, and 1-5, the creepage distance between the respective terminals and the cooling device 3 may be made longer. This makes it possible to reduce the height (that is, the length in the Z direction) of the outer frame 21 while maintaining an appropriate creepage distance. Alternatively, it is also possible to have terminals extend not only from the upper surface of the outer frame 21 but also from intermediate positions on the outer walls 21a, 21b, 21c, and 21d of the outer frame 21, while still achieving an appropriate creepage distance. By doing so, it becomes easy to change the height of the outer frame 21 and the arrangement of the terminals in the height direction (Z direction) while still achieving an appropriate creepage distance.

### Second Embodiment

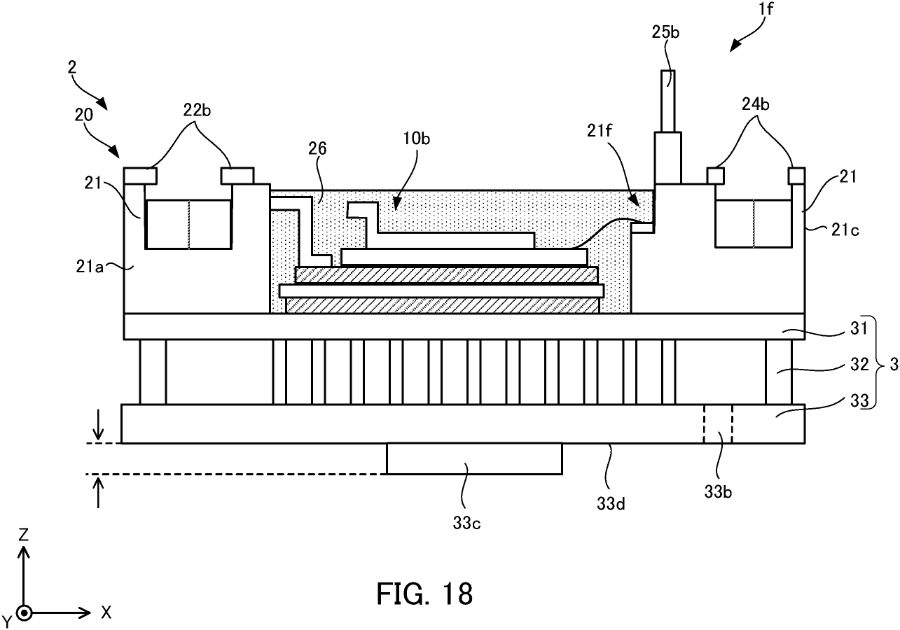

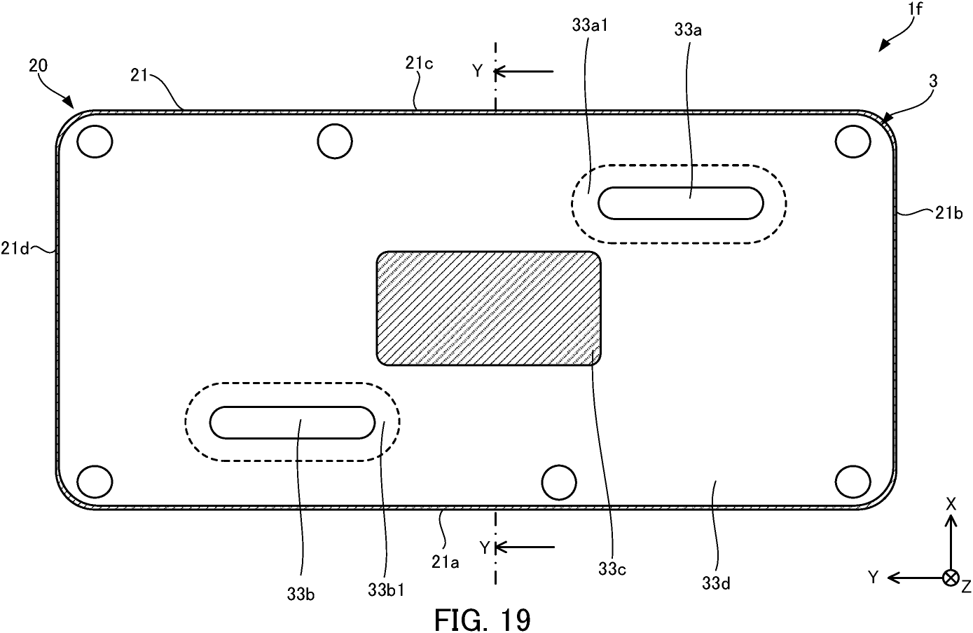

A semiconductor device according to a second embodiment will now be described with reference to FIGS. 18 and 19. FIG. 18 is a cross-sectional view of the semiconductor device according to the second embodiment, and FIG. 19 is a rear view of the semiconductor device according to the second embodiment. Note that FIG. 18 is a cross-sectional view taken along the dot-dash line Y-Y in FIG. 19.

The semiconductor device 1f also includes the semiconductor module 2 and the cooling device 3. The housing 20 included in the semiconductor module 2 is equipped with the outer frame 21 including the semiconductor units 10a, 10b, and 10c. The outer frame 21 in the second embodiment is joined to the cooling device 3. For this reason, the housing 20 may be regarded as including the outer frame 21 and the cooling device 3.

The cooling device 3 has the same configuration as in the first embodiment. A spacer portion 33c is provided in a central portion of the bottom surface 33d of the cooling bottom plate 33 of the cooling device 3 in the second embodiment. Note that corner portions of the spacer portion 33c may be chamfered into rounded or beveled shapes. Note also that the spacer portion 33c may be integrally formed with the bottom surface 33d of the cooling bottom plate 33.

Like the first embodiment, when the semiconductor device 1f described above is placed on an arbitrary placement surface, the spacer portion 33c produces a gap between the rear surface of the cooling device 3 (that is, the bottom surface 33d of the cooling bottom plate 33) and the placement surface. This means that the bottom surface 33d of the cooling bottom plate 33 does not directly touch the placement surface and is less likely to become damaged. Favorable sealing is therefore maintained between the pipes 37a and 37b, which are attached to the cooling device 3 of the semiconductor device 1f, and the inlet 33a and the outlet 33b of the cooling bottom plate 33. This prevents leaks of the coolant from the cooling device 3, suppresses a drop in the cooling performance of the cooling device 3, and enables the semiconductor units 10 to be appropriately cooled. As a result, it is possible to suppress any drop in reliability of the semiconductor device 1f.

The spacer portion 33c is disposed in a central portion of the bottom surface 33d of the cooling bottom plate 33 so that the semiconductor device 1f stably sits on a placement surface. In this configuration, the spacer portion 33c is positioned so as to avoid the sealing regions 33a1 and 33b1. The spacer portion 33c also has an appropriate area (size) that enables the semiconductor device 1f to stably sit on the placement surface. As one example, the lengths of long sides and short sides of the spacer portion 33c may be at least one third of the lengths of the long sides and the short sides of the cooling bottom plate 33. So long as the semiconductor device 1f is capable of sitting stably, the spacer portion 33c is not limited to being rectangular in plan view. As other examples, the spacer portion 33c may be triangular, star-shaped, circular, or elliptical. Alternatively, the spacer portion 33c may be hollow like a frame.

A spacer portion is provided in this way on the bottom surface 33d of the cooling bottom plate 33 of the cooling device 3 so that the cooling device 3 does not come into direct contact with the placement surface. Various forms of spacer portion are described below as modifications. Note that aside from the cooling bottom plate 33 of the semiconductor device 1f, the modifications described below include the same component elements as the semiconductor device 1f.

### Modification 2-1

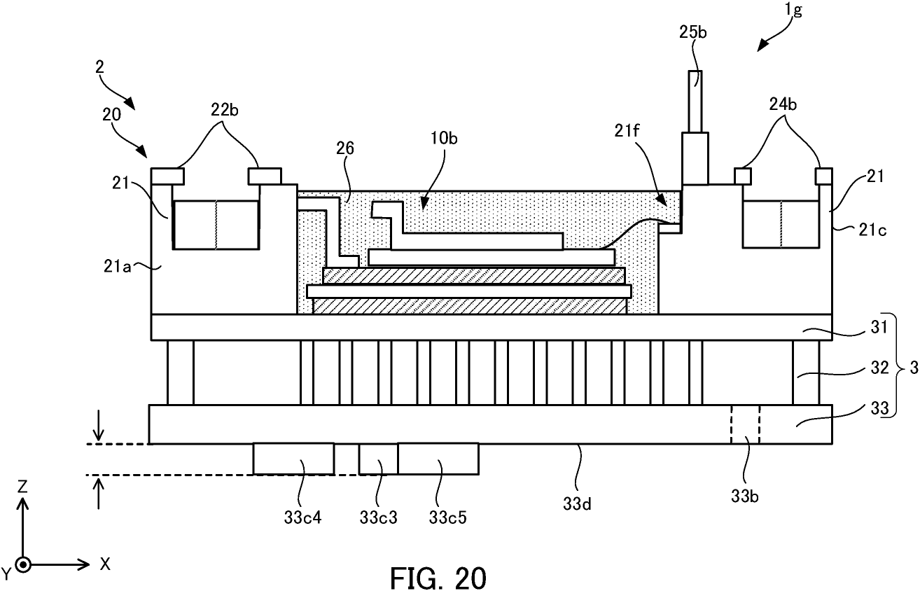

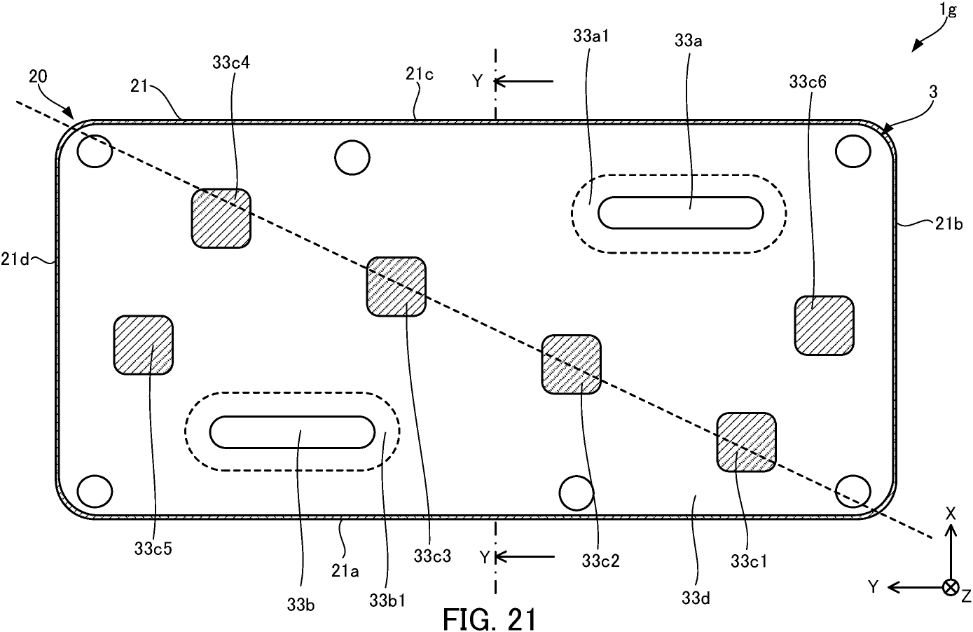

A semiconductor device 1g that is a modification 2-1 of the second embodiment will now be described with reference to FIGS. 20 and 21. FIG. 20 is a cross-sectional view of a semiconductor device according to the modification 2-1 of the second embodiment. FIG. 21 is a rear view of the semiconductor device according to the modification 2-1 of the second embodiment. Note that FIG. 20 is a cross-sectional view taken along a dot-dash line Y-Y in FIG. 21.

As described above, the bottom surface 33d of the cooling bottom plate 33 of the cooling device 3 included in the semiconductor device 1g is formed with the inlet 33a and the outlet 33b near opposite corners on one diagonal. A plurality of spacer portions 33c1, 33c2, 33c3, and 33c4 are provided on the bottom surface 33d of the cooling bottom plate 33 of the cooling device 3 along the other diagonal. Note that the number of spacer portions 33c1, 33c2, 33c3, and 33c4 is not limited to four and may be three, or five or higher. Alternatively, a bar-shaped spacer portion may be disposed on the other diagonal. In addition, spacer portions 33c5 and 33c6 are formed on the bottom surface 33d of the cooling bottom plate 33 of the cooling device 3 along lines in directions different from the other diagonal so as not to be provided in areas where the inlet 33a and the outlet 33b (and the sealing regions) are provided. For example, the lines in directions different from the other diagonal may be lines extending in directions that are perpendicular to (or intersect) the other diagonal, avoiding the inlet 33a and the outlet 33b (and the sealing regions). The spacer portions 33c5 and 33c6 are not limited to single spacer portions and it is possible to form two or more of each while avoiding the sealing regions 33a1 and 33b1.

In the same way as in the first embodiment, when the semiconductor device 1g described above is placed on an arbitrary placement surface, the spacer portions 33c1, 33c2, 33c3, and 33c4 and the spacer portions 33c5 and 33c6 produce a gap between the rear surface of the cooling device 3 (that is, the bottom surface 33d of the cooling bottom plate 33) and the placement surface. This means that the bottom surface 33d of the cooling bottom plate 33 does not directly contact the placement surface and is unlikely to become damaged. Accordingly, for the cooling device 3 of the semiconductor device 1g, it is possible to maintain a favorable seal for the connection between the pipes 37a and 37b and the inlet 33a and the outlet 33b on the cooling bottom plate 33. This prevents leaks of the coolant from the cooling device 3, suppresses a drop in the cooling performance of the cooling device 3, and enables the semiconductor units 10 to be appropriately cooled. As a result, it is possible to suppress any drop in reliability of the semiconductor device 1g.

In the same way as the spacer portion 33c in the second embodiment, so long as the semiconductor device 1g is capable of sitting stably on a placement surface, the spacer portions 33c1, 33c2, 33c3, 33c4, 33c5, and 33c6 are not limited to being rectangular in plan view, and as other examples, may be triangular, star-shaped, circular, or elliptical. Alternatively, the spacer portions may be semicircular.

### Modification 2-2

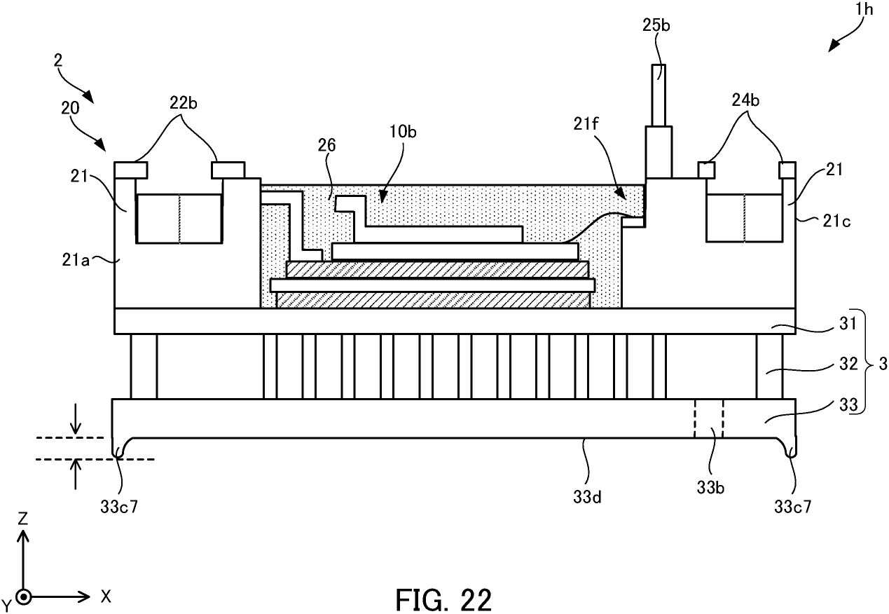

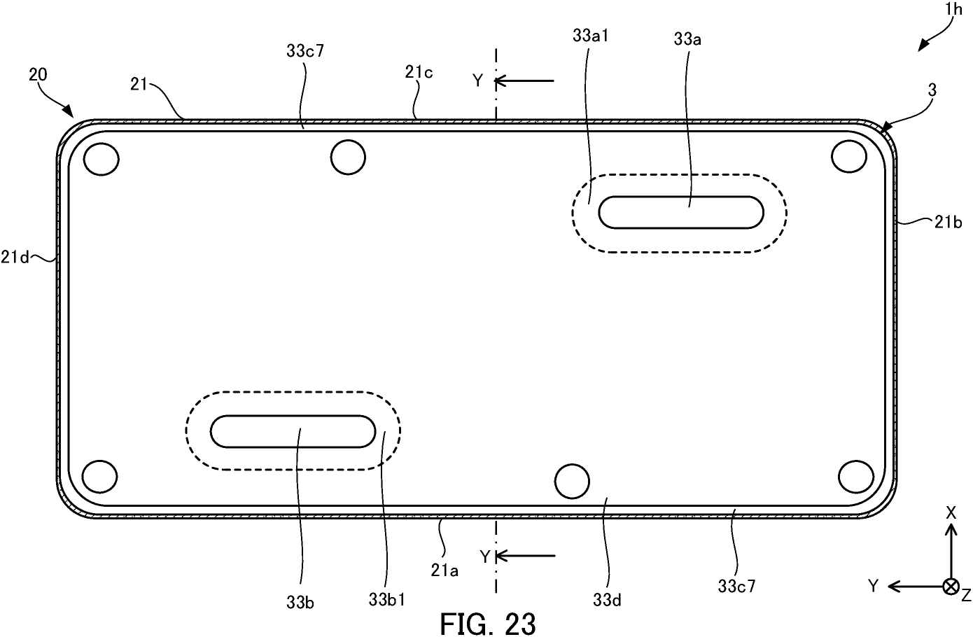

A semiconductor device that is a modification 2-2 of the second embodiment will now be described with reference to FIGS. 22 and 23. FIG. 22 is a cross-sectional view of the semiconductor device according to the modification 2-2 of the second embodiment. FIG. 23 is a rear view of the semiconductor device according to the modification 2-2 of the second embodiment. Note that FIG. 22 is a cross-sectional view taken along a dot-dash line Y-Y in FIG. 23.

A ring-shaped convex spacer portion 33c7 is formed continuously around the entire outer edge of the bottom surface 33d of the cooling bottom plate 33 of the cooling device 3 included in a semiconductor device 1h. As examples, the spacer portion 33c7 of this type is obtained by metal working, such as cutting, pressing, or rolling, so that the entire circumference of the outer edge protrudes from the bottom surface 33d of the cooling bottom plate 33.

Like the first embodiment, when the semiconductor device 1h is placed on an arbitrary placement surface, the spacer portion 33c7 produces a gap between the placement surface and the rear surface of the cooling device 3 (the bottom surface 33d of the cooling bottom plate 33). This means that the bottom surface 33d of the cooling bottom plate 33 does not directly touch the placement surface and is less likely to be damaged. Accordingly, for the cooling device 3 of the semiconductor device 1h, it is possible to connect the pipes 37a and 37b to the inlet 33a and the outlet 33b on the cooling bottom plate 33 with favorable sealing. This prevents leaks of the coolant from the cooling device 3, suppresses a drop in the cooling performance of the cooling device 3, and enables the semiconductor units 10 to be appropriately cooled. As a result, it is possible to suppress any drop in reliability of the semiconductor device 1h.

So long as a gap is produced between the rear surface of the cooling device 3 and the placement surface, the spacer portion 33c7 does not need to be formed around the entire circumference of the outer edge of the cooling bottom plate 33. As one example, in the same way as the spacer portions 21j2 (see FIG. 13) in the modification 1-3, the spacer portion 33c7 may be formed in at least a pair of diagonally opposite corner portions of the cooling bottom plate 33 in plan view. In this configuration, the spacer portion 33c7 is formed to surround the fastening holes 21i. Similarly, like the spacer portions 21k2 (see FIG. 15) in the modification 1-4, the spacer portion 33c7 may be formed so as to include at least parts facing the outer circumferences of the inlet 33a and the outlet 33b.

According to the present disclosure, it is possible to make the rear surface of a cooling device less susceptible to receiving damage, which enables coolant to flow into and out of the cooling device without leaking, suppresses a drop in cooling performance, and suppresses a drop in the reliability of a semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip; and
a housing including an outer frame and a cooling device, wherein the cooling device includes:
a top plate that has the semiconductor chip mounted on a front surface thereof;
a bottom plate that faces the top plate and has openings through each of which coolant flows in or out of the cooling device; and
a side wall that forms a continuous ring in a plan view of the semiconductor device, is interposed between the top plate and the bottom plate, and defines a flow path region within the ring, through which the coolant flows, and
the housing further includes a spacer portion that protrudes from a bottom surface of the bottom plate in a direction away from the semiconductor chip.

2. The semiconductor device according to claim 1, wherein
the outer frame is rectangular in the plan view and includes four outer walls that surround the cooling device and the semiconductor chip, and
the spacer portion is provided at a lower end portion of the outer walls at a cooling device-side thereof.

3. The semiconductor device according to claim 2, wherein
the bottom plate further has fastening holes respectively provided at corner portions thereof, and
the spacer portion is provided in plurality, the spacer portions being each provided at at least a corresponding one of diagonally opposite corner portions of the outer frame so as to cover a part of a corresponding one of outer peripheries of the fastening holes that faces the outer walls.

4. The semiconductor device according to claim 3, wherein the spacer portions are respectively provided at respective ones of all the corner portions of the outer frame so as to respectively cover parts of outer peripheries of the fastening holes that face the outer walls.

5. The semiconductor device according to claim 3, wherein
the openings include an inlet where the coolant flows into the cooling device and an outlet where the coolant flows out of the cooling device,
the inlet and the outlet are respectively provided in the bottom plate along a first diagonal line between diagonally opposite corner portions of the bottom plate, and
the spacer portions are respectively provided at the corner portions of the outer frame, which are parts of the lower end portion of the outer walls and adjacent to respective ones of the diagonally opposite corner portions of the outer frame, so as to cover parts of outer circumferences of the inlet and the outlet that face the outer walls.

6. The semiconductor device according to claim 2, wherein the spacer portion forms a continuous ring along the lower end portion of the outer walls.

7. The semiconductor device according to claim 2, wherein
the outer frame includes an external terminal with a first end portion that is electrically connected to the semiconductor chip and a second end portion that is exposed from the outer frame, and
the spacer portion is provided at a part of the lower end portion of the outer walls corresponding to a position that is directly below a position where the second end portion of the external terminal is exposed.

8. The semiconductor device according to claim 7, wherein
the outer frame includes the external terminal with the second end portion exposed from the outer frame, the second end portion being provided in plurality, and
the spacer portion is provided in plurality, and the plurality of spacer portions are respectively provided on the lower end portion of the outer walls at positions that are respectively directly below positions where the second end portions are exposed.

9. The semiconductor device according to claim 2, wherein
the spacer portion has a tab that extends inward in a direction parallel to the bottom plate.

10. The semiconductor device according to claim 2, further comprising a plurality of distribution heads provided on the bottom surface of the bottom plate of the cooling device, each distribution head having a first end that connects a corresponding one of the openings and a second end that extends in the direction away from the semiconductor chip, wherein
the spacer portion protrudes in the direction away from the semiconductor chip beyond the second end of each of the distribution heads.

11. The semiconductor device according to claim 1, further comprising a plurality of sealing regions provided on the bottom surface of the bottom plate of the cooling device in peripheries of the openings so as to surround respective ones of the openings, wherein
the spacer portion is provided on the bottom surface of the bottom plate in an area other than areas where the sealing regions are provided.

12. The semiconductor device according to claim 11, wherein the spacer portion has a column shape.

13. The semiconductor device according to claim 12, wherein the spacer portion is provided in an area including a center of the bottom surface of the bottom plate.

14. The semiconductor device according to claim 12, wherein
the openings include an inlet where the coolant flows into the cooling device and an outlet where the coolant flows out of the cooling device,
the inlet and the outlet are provided in the bottom plate along a first diagonal line between diagonally opposite corner portions of the bottom plate, and each are located closer to respective ones of the opposite corner portions than to between the opposite corner portions, and
the spacer portion is provided in plurality on the bottom surface of the bottom plate along a second diagonal line.

15. The semiconductor device according to claim 14, wherein the spacer portion also is provided in plurality on the bottom surface of the bottom plate along lines in directions different from the second diagonal line so as not to be provided in areas where the openings are provided.

16. The semiconductor device according to claim 11, wherein the spacer portion is provided at an outer edge of the bottom surface of the bottom plate.

17. The semiconductor device according to claim 16, wherein the spacer portion forms a continuous ring along the outer edge of the bottom surface of the bottom plate.

18. The semiconductor device according to claim 16, wherein
the bottom surface of the bottom plate includes fastening holes at each of the corner portions thereof, and
the bottom plate is rectangular in the plan view and the spacer portion is provided in plurality, each spacer portion being provided at at least diagonally opposite corner portions of the bottom plate so as to cover a part of a corresponding one of outer peripheries of the fastening holes that faces the outer frame.

19. The semiconductor device according to claim 16, wherein
the bottom plate is rectangular in the plan view,
the openings include, along a first diagonal line between diagonally opposite corner portions of the bottom plate, an inlet where the coolant flows into the cooling device and an outlet where the coolant flows out of the cooling device, and,
the spacer portion is provided in plurality, the spacer portions each being provided at a corresponding one of the diagonally opposite corner portions in the outer edge of the bottom surface of the bottom plate so as to cover a part of an outer circumference of a respective one of the inlet and the outlet that faces the outer frame.
